(19) United States
(12) Patent Application Publication
(10) Pub. No.: US 2026/0052822 A1
(43) Pub. Date: Feb. 19, 2026

(54) ELECTRONIC DEVICE AND METHOD OF MANUFACTURING ELECTRONIC DEVICE

(71) Applicant: InnoLux Corporation, Miao-Li County (TW)

(72) Inventors: Yuan-Lin WU, Miao-Li County (TW); Tsung-Han Tsai, Miao-Li County (TW); Kuan-Feng Lee, Miao-Li County (TW)

(73) Assignee: InnoLux Corporation, Miao-Li County (TW)

(21) Appl. No.: 19/269,052

(22) Filed: Jul. 15, 2025

(30) Foreign Application Priority Data
Aug. 16, 2024 (CN) 202411124921.9

(51) Int. Cl. H10H 29/49; H01L 25/075; H10H 29/01; H10H 29/02; H10H 29/34; H10H 29/85

(52) U.S. Cl. CPC H10H 29/49; H10H 29/012; H10H 29/02; H10H 29/0364; H10H 29/345; H10H 29/8508; H01L 25/0753

(57) ABSTRACT

An electronic device includes a flexible substrate, a circuit layer, a first electronic unit and a second electronic unit. The flexible substrate includes a main portion and a curve portion connected to the main portion. The circuit layer is disposed on the flexible substrate, and includes a first pad disposed on the main portion and a second pad disposed on the curve portion. The first electronic unit is bonded on the first pad. The second electronic unit is bonded on the second pad. An area of the second pad is different from an area of the first pad.

### BACKGROUND OF THE DISCLOSURE

### 1. Field of the Disclosure

The present disclosure relates to an electronic device and a method of manufacturing an electronic device, more particularly to an electronic device including an electronic unit disposed on a curve portion, and to a method of manufacturing this electronic device.

### 2. Description of the Prior Art

As the evolution and development of electronic devices, the electronic devices have become an indispensable item. For instance, a display device which is a kind of the electronic device has a displaying function, so as to transmit information and/or display an image.

If the electronic device is flexible and the periphery of the electronic device is bent, it must be considered whether the bending periphery affects the reliability of the electronic device. For instance, the electronic unit disposed on the bending periphery may fall off due to the bending, such that the reliability of the electronic device is affected. Accordingly, it is an important issue of producing a flexible electronic device with high quality and high reliability nowadays.

### SUMMARY OF THE DISCLOSURE

According to an embodiment, the present disclosure provides an electronic device including a flexible substrate, a circuit layer, a first electronic unit and a second electronic unit. The flexible substrate includes a main portion and a curve portion connected to the main portion. The circuit layer is disposed on the flexible substrate, and includes a first pad disposed on the main portion and a second pad disposed on the curve portion. The first electronic unit is bonded on the first pad. The second electronic unit is bonded on the second pad. An area of the second pad is different from an area of the first pad.

According to an embodiment, the present disclosure further provides an electronic device including a flexible substrate, a circuit layer, a first electronic unit, a second electronic unit, a third electronic unit and a fourth electronic unit. The flexible substrate includes a main portion and a curve portion connected to the main portion. The circuit layer is disposed on the flexible substrate, and includes a first pad, a second pad, a third pad, a fourth pad, a fifth pad, a sixth pad, a seventh pad and an eighth pad, wherein the first pad, the second pad, the third pad and the fourth pad are disposed on the main portion, and the fifth pad, the sixth pad, the seventh pad and the eighth pad are disposed on the curve portion. The first electronic unit is bonded on the first pad and the second pad. The second electronic unit is bonded on the third pad and the fourth pad. The third electronic unit is bonded on the fifth pad and the sixth pad. The fourth electronic unit is bonded on the seventh pad and the eighth pad. A first axis crossing a first center of the first pad and the second pad and a second center of the third pad and the fourth pad is not parallel to a second axis crossing a third center of the fifth pad and the sixth pad and a fourth center of the seventh pad and the eighth pad.

According to an embodiment, the present disclosure further provides a method of manufacturing an electronic device. The method includes following steps: providing a flexible substrate, wherein the flexible substrate comprises a first portion and a second portion; forming a circuit layer on the flexible substrate, wherein the circuit layer comprises a plurality of first pads disposed on the first portion and a plurality of second pads disposed on the second portion; patterning the second portion to form a plurality of trenches; transferring a plurality of first electronic units to the plurality of first pads by at least one first transfer process; transferring a plurality of second electronic units to the plurality of second pads by at least one second transfer process; and bending the second portion with respect to the first portion. A number of the first electronic units transferred by one of the at least one first transfer process is different from a number of the second electronic units transferred by one of the at least one second transfer process.

### BRIEF DESCRIPTION OF THE DRAWINGS

FIG. 1 is a schematic diagram showing a flexible substrate of an electronic device according to an embodiment of the present disclosure.

FIG. 2 is a schematic diagram showing a top view of a flexible substrate and pads of an electronic device according to a first embodiment of the present disclosure.

FIG. 3 is a schematic diagram showing a cross-sectional view of an electronic device according to the first embodiment of the present disclosure.

FIG. 4 is a schematic diagram showing a top view of a flexible substrate and pads of an electronic device according to a second embodiment of the present disclosure.

FIG. 5 is a schematic diagram showing a top view of a flexible substrate and pads of an electronic device according to a third embodiment of the present disclosure.

FIG. 6 is a schematic diagram showing a top view of a flexible substrate and pads of an electronic device according to a fourth embodiment of the present disclosure.

FIG. 7 is a schematic diagram showing a cross-sectional view of an electronic device according to the fifth embodiment of the present disclosure.

FIG. 8 is a schematic diagram showing a top view of a flexible substrate and pads of an electronic device according to a sixth embodiment of the present disclosure.

FIG. 9 is a schematic diagram showing a top view of a flexible substrate and pads of an electronic device according to a seventh embodiment of the present disclosure.

FIG. 10 is a schematic diagram showing a top view of designs of a curving-portion pad of an electronic device according to the seventh embodiment of the present disclosure.

FIG. 11 is a schematic diagram showing a top view of a flexible substrate and pads of an electronic device according to an eighth embodiment of the present disclosure.

FIG. 12 is a schematic diagram showing a top view of a flexible substrate and pads of an electronic device according to a ninth embodiment of the present disclosure.

FIG. 13 is a schematic diagram showing a cross-sectional view of an electronic device according to a tenth embodiment of the present disclosure.

FIG. 14 is a schematic diagram showing a top view of a flexible substrate, pads and designs of a curve portion of an electronic device according to an eleventh embodiment of the present disclosure.

FIG. 15 is a schematic diagram showing a top view of a flexible substrate and pads of an electronic device according to a twelfth embodiment of the present disclosure.

FIG. 16 is a schematic diagram showing a cross-sectional view of designs of a curving-portion electronic unit of an electronic device according to the twelfth embodiment of the present disclosure.

FIG. 17 is a schematic diagram showing a flowchart of a method of manufacturing an electronic device according to an embodiment of the present disclosure.

FIG. 18 to FIG. 21 are schematic diagrams showing structures at different steps of a method of manufacturing an electronic device according to an embodiment of the present disclosure.

FIG. 22 is a schematic diagram showing a top view of designs of a transferring substrate according to an embodiment of the present disclosure.

FIG. 23 is a schematic diagram showing a top view of an electronic device according to a thirteenth embodiment of the present disclosure.

### DETAILED DESCRIPTION

The present disclosure may be understood by reference to the following detailed description, taken in conjunction with the drawings as described below. It is noted that, for purposes of illustrative clarity and being easily understood by the readers, various drawings of this disclosure show a portion of an electronic device in this disclosure, and certain elements in various drawings may not be drawn to scale. In addition, the number and dimension of each device shown in drawings are only illustrative and are not intended to limit the scope of the present disclosure.

Certain terms are used throughout the description and following claims to refer to particular components. As one skilled in the art will understand, electronic equipment manufacturers may refer to a component by different names. This document does not intend to distinguish between components with the same function but different names.

In the following description and in the claims, the terms “include”, “comprise” and “have” are used in an open-ended fashion, and thus should be interpreted to mean “include, but not limited to . . . ”. Thus, when the terms “include”, “comprise” and/or “have” are used in the description of the present disclosure, the corresponding features, regions, steps, operations and/or components would be pointed to existence, but not limited to the existence of one or a plurality of the corresponding features, regions, steps, operations and/or components.

The directional terms used throughout the description and following claims, such as: “on”, “up”, “above”, “down”, “below”, “front”, “rear”, “back”, “left”, “right”, etc., are only directions referring to the drawings. Therefore, the directional terms are used for explaining and not used for limiting the present disclosure. Regarding the drawings, the drawings show the general characteristics of methods, structures, and/or materials used in specific embodiments. However, the drawings should not be construed as defining or limiting the scope or properties encompassed by these embodiments. For example, for clarity, the relative size, thickness, and position of each layer, each region, and/or each structure may be reduced or enlarged.

When the corresponding component such as layer or region is referred to “on another component”, it may be directly on this another component, or other component(s) may exist between them. On the other hand, when the component is referred to “directly on another component (or the variant thereof)”, any component does not exist between them. Furthermore, when the corresponding component is referred to “on another component”, the corresponding component and the another component have a disposition relationship along a top-view/vertical direction, the corresponding component may be below or above the another component, and the disposition relationship along the top-view/vertical direction are determined by an orientation of the device.

It will be understood that when a component or layer is referred to as being “connected to” another component or layer, it can be directly connected to this another component or layer, or intervening components or layers may be presented. In contrast, when a component is referred to as being “directly connected to” another component or layer, there are no intervening components or layers presented. In addition, when the component is referred to “be coupled to/with another component (or the variant thereof)”, it may be directly connected to this another component, or may be indirectly connected (such as electrically connected) to this another component through other component(s).

In the description and following claims, the term “horizontal direction” generally means a direction parallel to a horizontal plane, the term “horizontal plane” generally means a surface parallel to a direction X and direction Y in the drawings, the term “vertical direction” generally means a direction parallel to a direction Z and perpendicular to the horizontal direction in the drawings, and the direction X, the direction Y and the direction Z are perpendicular to each other. In the description and following claims, the term “top view” generally means a viewing result viewing along the vertical direction. In the description and following claims, the term “cross-sectional view” generally means a structure cut along the vertical direction is viewed along the horizontal direction.

In the description and following claims, it should be noted that the term “overlap” means that two elements overlap along the direction Z, and the term “overlap” can be “partially overlap” or “completely overlap” in unspecified circumstances.

The terms “about”, “approximately”, “substantially”, “equal”, or “same” generally mean within ±20% of a given value or range, or mean within ±10%, ±5%, ±3%, ±2%, ±1%, or ±0.5% of a given value or range.

Although terms such as first, second, third, etc., may be used to describe diverse constituent elements, such constituent elements are not limited by the terms. These terms are used only to discriminate a constituent element from other constituent elements in the specification, and these terms have no relation to the manufacturing order of these constituent components. The claims may not use the same terms, but instead may use the terms first, second, third, etc. with respect to the order in which an element is claimed. Accordingly, in the following description, a first constituent element may be a second constituent element in a claim.

It should be noted that the technical features in different embodiments described in the following can be replaced, recombined, or mixed with one another to constitute another embodiment without departing from the spirit of the present disclosure.

In the present disclosure, the electronic device may include a display device, a lighting device, an antenna device, a sensing device, a tiled device or a combination thereof, but not limited thereto. The display device may be a non-self-luminous type display device or a self-luminous type display device based on requirement(s), and the display device may be a color display device or a monochrome display device based on requirement(s). The antenna device may be a liquid-crystal-type antenna device or a non-liquid-crystal-type antenna device, the sensing device may be a device for sensing capacitance, light, thermal or ultrasonic, and the tiled device may be a tiled display device or a tiled antenna device, but not limited thereto. Electronic components in the electronic device may include passive component(s) and active component(s), such as capacitor(s), resistor(s), inductor(s), diode(s), transistor(s) and/or integrated circuit(s), but not limited thereto. The diode may include a light emitting diode (LED) or a photodiode. The light emitting diode may include an organic light emitting diode (OLED), a mini LED, a micro LED or a quantum dot LED, but not limited thereto. The transistor may include a top gate thin film transistor, a bottom gate thin film transistor or a dual gate thin film transistor, but not limited thereto. The electronic device may include fluorescence material, phosphorescence material, quantum dot (QD) material or other suitable material based on requirement(s), but not limited thereto. The electronic device may have a peripheral system (such as a driving system, a control system, a light system, etc.) for supporting the device(s) and the component(s) in the electronic device.

For example, the electronic device described in the following may have a displaying function and be flexible to show technical features of the present disclosure, but the electronic device of the present disclosure is not limited by the following contents.

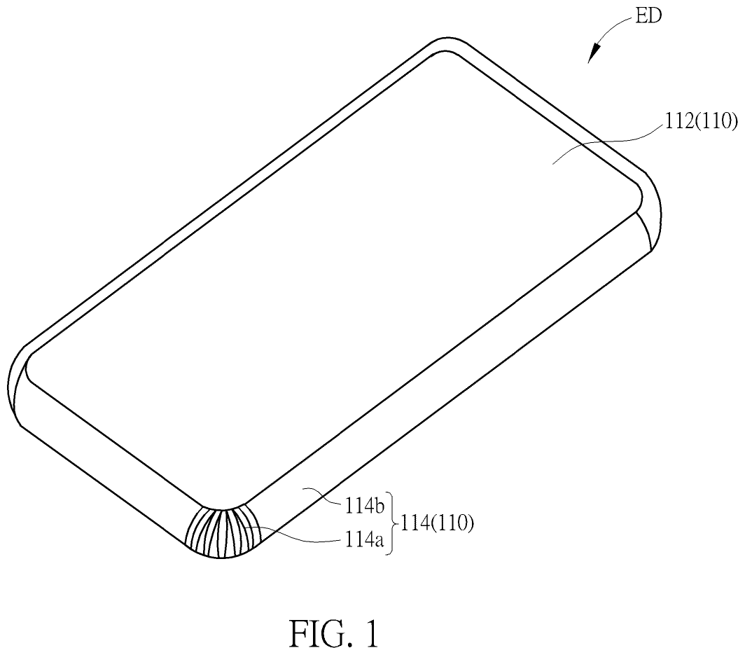

Referring to FIG. 1, FIG. 1 is a schematic diagram showing a flexible substrate of an electronic device according to an embodiment of the present disclosure. As shown in FIG. 1, the electronic device ED includes a flexible substrate 110, wherein the flexible substrate 110 may include any suitable rigid material and/or flexible material. In some embodiments, if the flexible substrate 110 includes the rigid material, the rigid material can be made flexible by reducing a thickness of the rigid material and/or forming at least one opening in the rigid material. For instance, the flexible substrate 110 may include glass, quartz, ceramic, sapphire, polymer (e.g., polyimide (PI), polyethylene terephthalate (PET), polymethyl methacrylate (PMMA), etc.), other suitable materials or a combination thereof.

In the present disclosure, the flexible substrate 110 may be bent at a desired position to make the electronic device ED achieve a desired shape. In FIG. 1, the flexible substrate 110 may include a main portion 112 (the main portion 112 may be referred as a first portion) and a curve portion 114 (the curve portion 114 may be referred as a second portion) connected to the main portion 112, wherein the main portion 112 may be slightly bent or not be bent, the curve portion 114 may have a greater curvature with respect to the main portion 112, and a normal direction of the main portion 112 of the flexible substrate 110 may be parallel to the direction Z. In some embodiments (as shown in FIG. 1), the main portion 112 may be a non-bent region, and the curve portion 114 may surround the main portion 112 and be substantially bent toward a negative direction of the direction Z (e.g., in FIG. 1, the periphery of the flexible substrate 110 may be bent downwards). For instance, the curve portion 114 may include a plurality of corner regions 114a and optionally include a plurality of fringe regions 114b, wherein the corner region 114a may be connected to a corner of the main portion 112, the fringe region 114b may be connected to an edge of the main portion 112 extending along the horizontal direction, the corner region 114a may be connected to two fringe regions 114b in different horizontal directions, and the fringe region 114b may be connected between two corner regions 114a, but not limited thereto. For instance, the Gaussian curvature of the fringe region 114b may be 0 such that the fringe region 114b may be similar to a curved side surface of a cylinder, and the Gaussian curvature of the corner region 114a may not be equal to 0 (e.g., the Gaussian curvature of the corner region 114a may be greater than 0 such that the corner region 114a may be similar to a spherical surface), but not limited thereto.

In the present disclosure, since the main portion 112 and the curve portion 114 of the flexible substrate 110 have different curvatures, a disposition of electronic units on the main portion 112 and a disposition of electronic units on the curve portion 114 of the electronic device ED may have different designs, such that the electronic units may be well disposed on the main portion 112 and the curve portion 114 with different curvatures to make the falling possibility of the electronic unit on the curve portion 114 be reduced, thereby enhancing the reliability of the electronic device ED.

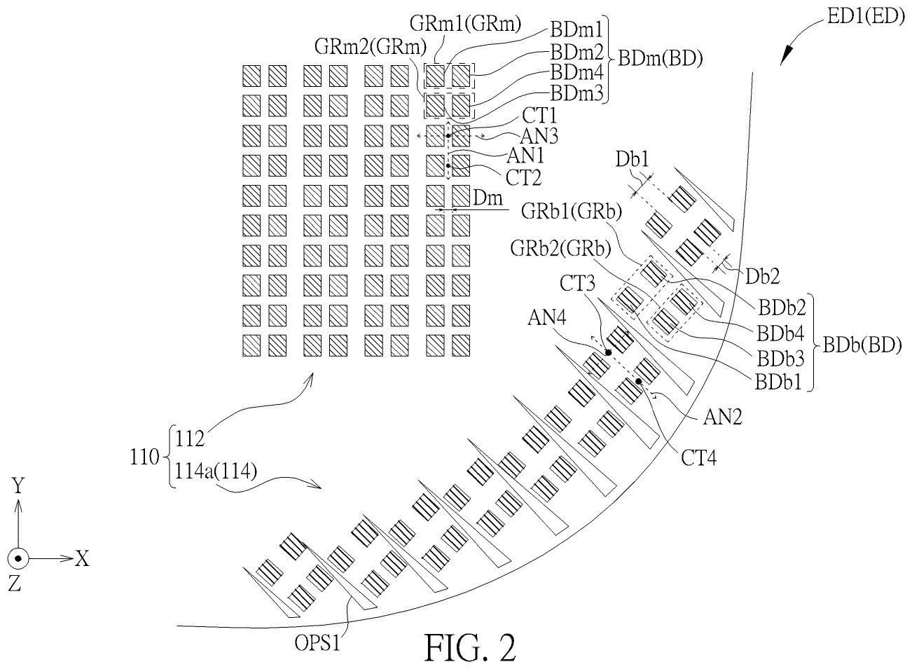

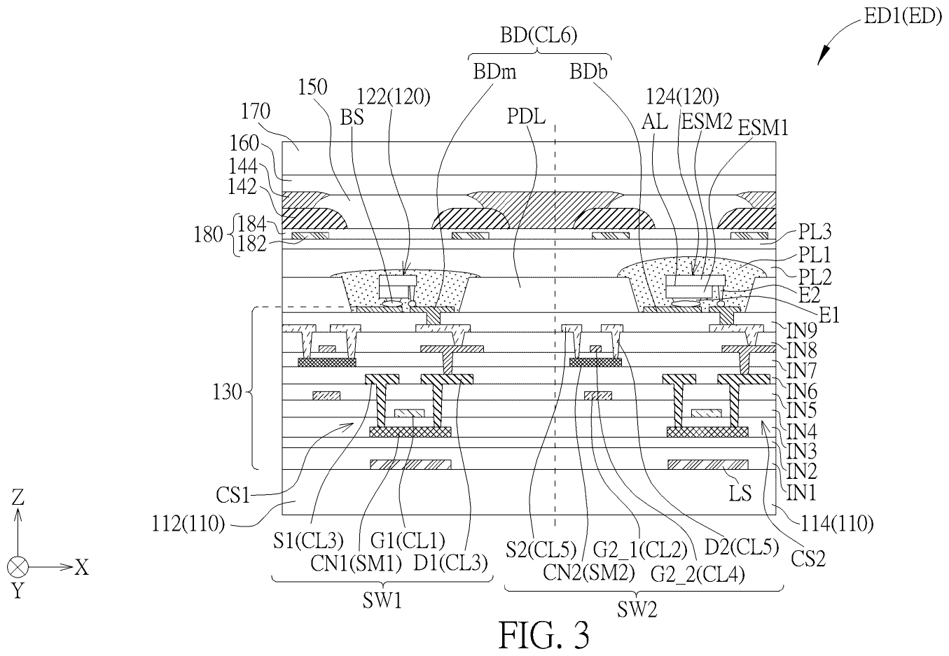

Referring to FIG. 2 and FIG. 3, FIG. 2 is a schematic diagram showing a top view of a flexible substrate and pads of an electronic device according to a first embodiment of the present disclosure, and FIG. 3 is a schematic diagram showing a cross-sectional view of an electronic device according to the first embodiment of the present disclosure, wherein FIG. 2 shows the flexible substrate 110 before bending (i.e., the flexible substrate 110 is in a fully flat state), and FIG. 2 shows a part of the main portion 112 and the corner region 114a of the curve portion 114. As shown in FIG. 2, the flexible substrate 110 of the electronic device ED1 may have an appropriate patterning design (e.g., opening(s) and/or slit(s)), such that the curve portion 114 may be bent into a required shape according requirement(s). In some embodiments (as shown in FIG. 2), the corner region 114a of the curve portion 114 of the flexible substrate 110 may have a plurality of first substrate openings OPS1, such that the corner region 114a may be bent into a spherical surface in a highly reliable manner, and two overlapping regions of the corner region 114a due to secondary bending may be reduced or be avoided. For instance (as shown in FIG. 2), the first substrate opening OPS1 may extend along a horizontal direction and may be a strip type opening (e.g., a triangular opening with the strip type), and an extending direction of the first substrate opening OPS1 may not be parallel to the direction X and the direction Y, but not limited thereto. For instance (as shown in FIG. 2), the first substrate opening OPS1 may substantially extend from an edge (or a corner) of the flexible substrate 110 to an edge (or a corner) of the main portion 112 of the flexible substrate 110, and the extending directions of the first substrate openings OPS1 may be the same or different, but not limited thereto.

As shown in FIG. 3, the electronic device ED1 may include a plurality of electronic units 120 disposed on the flexible substrate 110, wherein the electronic unit 120 may be any suitable electronic component. In some embodiments, the electronic unit 120 may be a light emitting unit, such as a LED (e.g., an OLED, a mini LED, a micro LED or a quantum dot LED), or an integrated light emitting chip (e.g., one integrated light emitting chip may include a plurality of light emitting elements), but not limited thereto. In some embodiments, the electronic unit 120 may be disposed on the flexible substrate 110 by a bonding process, but not limited thereto. For example (in FIG. 3), the electronic unit 120 may be a light emitting unit disposed on the flexible substrate 110 by the bonding process, but not limited thereto. Since the electronic device ED1 has the displaying function, the electronic unit 120 of the electronic device ED1 may be the light emitting unit configured to display an image.

In the present disclosure, the electronic unit 120 serving as the light emitting unit may be designed based on requirement(s). For instance, in FIG. 3, the electronic unit 120 may include an electrode E1, an electrode E2, a semiconductor layer ESM1, a semiconductor layer ESM2 and a light emitting layer AL, wherein the electrode E1 may be electrically connected to the semiconductor layer ESM1, the electrode E2 may be electrically connected to the semiconductor layer ESM2, and the light emitting layer AL may be disposed between the semiconductor layer ESM1 and the semiconductor layer ESM2, but not limited thereto. For instance, the semiconductor layer ESM1 may be a P-type semiconductor layer, the semiconductor layer ESM2 may be an N-type semiconductor layer, and the light emitting layer AL may be a multiple quantum well (MQW), but not limited thereto. In addition, the electrode E1 and the electrode E2 may serve as structures in the electronic unit 120 electrically connected to other electronic component(s), and the electrode E1 and the electrode E2 may be electrically connected to other electronic component(s) by any suitable manner (e.g., a bonding process). For instance, the electrode E1 and the electrode E2 may be pins of the electronic unit 120, but not limited thereto. Moreover, in some embodiments (as shown in FIG. 3), the electrode E1 and the electrode E2 may be disposed on the same side of the electronic unit 120 (i.e., the electrode E1 and the electrode E2 may be disposed on the same side of the semiconductor layer ESM2), such that the electronic unit 120 may be a flip chip type light emitting unit, but not limited thereto.

In the present disclosure, the electronic units 120 serving as the light emitting units may generate the lights with the same color or different colors. For instance, the electronic units 120 may generate the lights with different colors (e.g., the electronic units 120 may respectively generate a red light, a green light and a blue light), such that the electronic device ED1 may be capable of displaying an color image, but not limited thereto. For instance, the electronic unit 120 may generate the lights with the same color (e.g., a white light), such that the electronic device ED1 may be capable of displaying a monochrome image, but not limited thereto. For instance, the electronic unit 120 may generate the lights with the same color (e.g., an ultraviolet (UV) light or a blue light), and the color of these lights may be converted into other color(s) through a color converting structure (e.g., a color converting layer 150), such that the electronic device ED1 may be capable of displaying an color image, but not limited thereto.

In the present disclosure, the plurality of electronic units 120 may be divided into a plurality of main-portion electronic units 122 (e.g., the main-portion electronic units 122 may be referred as first electronic units) and a plurality of curving-portion electronic units 124 (e.g., the curving-portion electronic units 124 may be referred as the second electronic units) according to the positions of the electronic units 120, wherein the main-portion electronic unit 122 may be disposed on the main portion 112 of the flexible substrate 110, the curving-portion electronic unit 124 may be disposed on the curve portion 114 of the flexible substrate 110, and the curving-portion electronic unit 124 may be disposed between two first substrate openings OPS1.

As shown in FIG. 3, the electronic device ED1 may include a circuit layer 130 disposed between the flexible substrate 110 and the electronic unit 120 (e.g., the light emitting unit). In the present disclosure, the circuit layer 130 may include at least one conductive layer, at least one insulating layer, at least one semiconductor layer, other required layer or a combination thereof, such that the electronic components and the circuit may be included in the circuit layer 130. The material of the conductive layer may include metal, transparent conductive material (e.g., indium tin oxide (ITO), indium zinc oxide (IZO), etc.), other suitable conductive material(s) or a combination thereof, the material of the insulating layer may include inorganic insulating material (e.g., silicon oxide (SiOₓ), silicon nitride (SiN_{y}), silicon oxynitride (SiOₓN_{y})), organic insulating material (e.g., photosensitive resin), other suitable insulating material(s) or a combination thereof, and the material of the semiconductor layer may include poly-silicon, amorphous silicon, metal-oxide semiconductor, other suitable semiconductor material(s) or a combination thereof, but not limited thereto.

In the circuit layer 130 of the present disclosure, a number of the conductive layer(s), a number of the insulating layer(s), a number of the semiconductor layer(s) and a stacking order of these layers may be adjusted based on the type of the electronic component and the circuit design. For instance, in FIG. 3, the circuit layer 130 may include an insulating layer IN1, an insulating layer IN2, a semiconductor layer SM1, an insulating layer IN3, a conductive layer CL1, an insulating layer IN4, a conductive layer CL2, an insulating layer IN5, a conductive layer CL3, an insulating layer IN6, a semiconductor layer SM2, an insulating layer IN7, a conductive layer CL4, an insulating layer IN8, a conductive layer CL5, an insulating layer IN9 and a conductive layer CL6 stacked in sequence, but not limited thereto. The insulating layer IN1 may be a buffer layer, such that other layers in the circuit layer 130 may be disposed on the flexible substrate 110 well.

In some embodiments (as shown in FIG. 3), the circuit layer 130 may include a first switching component SW1 (e.g., a top gate thin film transistor), wherein a gate electrode G1 of the first switching component SW1 may be included in the conductive layer CL1, a source electrode S1 and a drain electrode D1 of the first switching component SW1 may be included in the conductive layer CL3, and a channel layer CN1 of the first switching component SW1 may be included in the semiconductor layer SM1, but not limited thereto. For instance, in FIG. 3, the first switching component SW1 may be electrically connected to the electronic unit 120 (e.g., the light emitting unit), but not limited thereto. Furthermore, the circuit layer 130 may further include a light blocking layer LS disposed between the flexible substrate 110 and the insulating layer IN1 and overlapping the channel layer CN1 of the first switching component SW1, so as to reduce the probability that the channel layer CN1 is irradiated by the light. For instance, the light blocking layer LS may include metal, photoresist, ink, resin, pigment, other suitable light blocking material(s) or a combination thereof, but not limited thereto.

In some embodiments (as shown in FIG. 3), the circuit layer 130 may include a second switching component SW2 (e.g., a dual gate thin film transistor), wherein gate electrodes G2_1 and G2_2 of the second switching component SW2 may be respectively included in the conductive layer CL2 and the conductive layer CL4, a source electrode S2 and a drain electrode D2 of the second switching component SW2 may be included in the conductive layer CL5, and a channel layer CN2 of the second switching component SW2 may be included in the semiconductor layer SM2, but not limited thereto. Furthermore, the gate electrode G2_1 included in the conductive layer CL2 may reduce the probability that the channel layer CN2 is irradiated by the light.

In the present disclosure, the circuit layer 130 may include a plurality of pads BD, wherein the pad BD may be included in the topmost conductive layer in the circuit layer 130, and the pad BD may be configured to bonded with the electronic component (e.g., the electronic unit 120, the driving circuit chip, etc.) disposed on the circuit layer 130, such that the electronic component (e.g., the switching component) in the circuit layer 130 may be electrically connected to the electronic component (e.g., the electronic unit 120, the driving circuit chip, etc.) disposed on the circuit layer 130 through the pad BD, so as to form a required circuit. For instance, in FIG. 3, the pad BD may a structure belonging to the conductive layer CL6, and the first switching component SW1 (e.g., the drain electrode) of the circuit layer 130 may be electrically connected to the pad BD through a connecting structure in the conductive layer CL4 and a connecting structure in the conductive layer CL5, thereby being electrically connected to the electronic unit 120 (e.g., the light emitting unit), but not limited thereto. In addition, a shape of the pad BD in the top view may be a polygon (e.g., a rectangle), a shape having a curved edge (e.g., a circle, an oval or a polygon with curved chamfers) or other suitable shape. For instance, in FIG. 2, the shape of the pad BD in the top view may be a rectangle, but not limited thereto.

In the present disclosure, the plurality of pads BD may be divided into a plurality of main-portion pads BDm and a plurality of curving-portion pads BDb according to the positions of the pads BD (although the top view diagram shows the main-portion pad BDm and the curving-portion pad BDb with different shadings, the main-portion pad BDm and the curving-portion pad BDb may be included in the same conductive layer), wherein the main-portion pad BDm may be disposed on the main portion 112 of the flexible substrate 110 and be electrically connected to the first circuit CS1 (e.g., the first circuit CS1 may include the switching component, the driving circuit chip and/or other electronic component), and the curving-portion pad BDb may be disposed on the curve portion 114 of the flexible substrate 110 and be electrically connected to the second circuit CS2 (e.g., the second circuit CS2 may include the switching component, the driving chip and/or other electronic component). In FIG. 3, the main-portion electronic unit 122 may be bonded on the main-portion pad BDm through a bonding component BS (e.g., solder), and the curving-portion electronic unit 124 may be bonded on the curving-portion pad BDb through a bonding component BS. Moreover, since the electronic unit 120 shown in FIG. 3 is a flip chip type light emitting unit, two electrodes of the main-portion electronic unit 122 may be respectively bonded on two main-portion pads BDm (in the following, two main-portion pads BDm corresponding to the same main-portion electronic unit 122 may be referred as a main-portion pad group GRm), and two electrodes of the curving-portion electronic unit 124 may be respectively bonded on two curving-portion pads BDb (in the following, two curving-portion pads BDb corresponding to the same curving-portion electronic unit 124 may be referred as a curving-portion pad group GRb), but not limited thereto. Furthermore, in FIG. 2, the curving-portion pad BDb may be disposed between two first substrate openings OPS1, such that the curving-portion electronic unit 124 may be disposed between two first substrate openings OPS1, but not limited thereto.

In the present disclosure, a design consideration of the main-portion pad BDm and a design consideration of the main-portion electronic unit 122 are different from a design consideration of the curving-portion pad BDb and a design consideration of the curving-portion electronic unit 124, wherein the designs of the main-portion pad BDm and the main-portion electronic unit 122 are based on the displaying quality of the main portion 112, and the designs of the curving-portion pad BDb and the curving-portion electronic unit 124 are based on the displaying quality of the curve portion 114 and the falling possibility of the curving-portion electronic unit 124. In some embodiments, the position of the curving-portion pad BDb may avoid a region with the maximum curvature in the curve portion 114 of the flexible substrate 110, such that the bending stress on the curving-portion pad BDb and/or the curving-portion electronic unit 124 bonded on the curving-portion pad BDb is reduced, so as to decrease the falling possibility of the curving-portion electronic unit 124, thereby enhancing the reliability of the electronic device ED1. For instance, the position of the curving-portion pad BDb may be situated in a region with a small curvature in the curve portion 114 of the flexible substrate 110, but not limited thereto.

In some embodiments (as shown in FIG. 2), since the design consideration of the main-portion pad BDm and the design consideration of the main-portion electronic unit 122 are different from the design consideration of the curving-portion pad BDb and the design consideration of the curving-portion electronic unit 124, a relation between two adjacent main-portion pad groups GRm is different from a relation between two adjacent curving-portion pad groups GRb. In a first main-portion pad group GRm1 and a second main-portion pad group GRm2 which h are adjacent (i.e., two main-portion pad groups GRm closest to each other), the first axis AN1 crosses a first center CT1 of the first main-portion pad group GRm1 (i.e., the first center CT1 is related to two main-portion pads BDm1 and BDm2 in the first main-portion pad group GRm1) and a second center CT2 of the second main-portion pad group GRm2 (i.e., the second center CT2 is related to two main-portion pads BDm3 and BDm4 in the second main-portion pad group GRm2). In a first curving-portion pad group GRb1 and a second curving-portion pad group GRb2 which are adjacent (i.e., two curving-portion pad groups GRb closest to each other), the second axis AN2 crosses a third center CT3 of the first curving-portion pad group GRb1 (i.e., the third center CT3 is related to two curving-portion pads BDb1 and BDb2 in the first curving-portion pad group GRb1) and a fourth center CT4 of the second curving-portion pad group GRb2 (i.e., the fourth center CT4 is related to two curving-portion pads BDb3 and BDb4 in the second curving-portion pad group GRb2). In FIG. 2, the first axis AN1 is not parallel to the second axis AN2, such that the relation between the first main-portion pad group GRm1 and the second main-portion pad group GRm2 is different from the relation between the first curving-portion pad group GRb1 and the second curving-portion pad group GRb2. For instance, an angle between the first axis AN1 and the second axis AN2 may be greater than or equal to 5 degrees and less than or equal to 90 degrees to make this angle is an acute angle or a right angle, but not limited thereto. The center of the main-portion pad group GRm is a geometric center of a minimum outline (e.g., a minimum quadrilateral) covering two main-portion pads BDm of this main-portion pad group GRm in the condition that the flexible substrate 110 is in the fully flat state, and the center of the curving-portion pad group GRb is a geometric center of a minimum outline (e.g., a minimum quadrilateral) covering two curving-portion pads BDb of this curving-portion pad group GRb in the condition that the flexible substrate 110 is in the fully flat state.

Since the first axis AN1 is not parallel to the second axis AN2, an arrangement of the main-portion pads BDm and an arrangement of the curving-portion pads BDb are different. In some embodiments (as shown in FIG. 2), the main-portion pads BDm (or the main-portion pad groups GRm) may be arranged into a plurality of rows extending along the direction X and into a plurality of columns extending along the direction Y, such that the first axis AN1 may be parallel to the direction X or the direction Y (in FIG. 2, the first main-portion pad group GRm1 and the second main-portion pad group GRm2 may be adjacent in the direction Y, such that the first axis AN1 may be parallel to the direction Y), but not limited thereto. In some embodiments (as shown in FIG. 2), the arranging direction of the curving-portion pads BDb in one curving-portion pad group GRb may be substantially perpendicular to the extending direction of the first substrate opening OPS1, and the curving-portion pad groups GRb may be substantially arranged along the extending direction of the first substrate opening OPS1, such that the second axis AN2 may not be parallel to the first axis AN1, but not limited thereto. For example, in FIG. 2, the second axis AN2 may be substantially parallel to the extending direction of the first substrate opening OPS1, but not limited thereto.

In some embodiments (as shown in FIG. 2), a rotating relation may exist between the main-portion pad BDm and the curving-portion pad BDb. For example, in FIG. 2, an edge of the main-portion pad BDm may be parallel to the direction X, another edge of the main-portion pad BDm may be parallel to the direction Y, an edge of the curving-portion pad BDb may be substantially parallel to the extending direction of the first substrate opening OPS1, and another edge of the curving-portion pad BDb may be substantially perpendicular to the extending direction of the first substrate opening OPS1, but not limited thereto. In another aspect, in FIG. 2, a third axis AN3 may cross a center of the main-portion pad BDm1 and a center of the main-portion pad BDm2 of the first main-portion pad group GRm1, a fourth axis AN4 may cross a center of the curving-portion pad BDb1 and a center of the curving-portion pad BDb2 of the first curving-portion pad group GRb1, and the third axis AN3 may not parallel to the fourth axis AN4, but not limited thereto. Through this arrangement, the number and the density of the curving-portion pads BDb in the curve portion 114 may be enhanced, thereby enhancing the number and the density of the curving-portion electronic units 124 in the curve portion 114 (e.g., the displaying quality of the curve portion 114 is enhanced). The center of the main-portion pad BDm is a geometric center of the main-portion pad BDm in the condition that the flexible substrate 110 is in the fully flat state, and the center of the curving-portion pad BDb is a geometric center of the curving-portion pad BDb in the condition that the flexible substrate 110 is in the fully flat state.

In the present disclosure, a distance between two main-portion pads BDm (i.e., two adjacent main-portion pads BDm) in the main-portion pad group GRm and a distance between two curving-portion pads BDb (i.e., two adjacent curving-portion pads BDb) in the curving-portion pad group GRb may be designed based on requirement(s), wherein a distance between two pads BD is the minimum distance between two pads BD, and a measuring direction of this distance is parallel to a line connected between these two pads BD. In the present disclosure, the distance between two main-portion pads BDm in the main-portion pad group GRm and the distance between two curving-portion pads BDb in the curving-portion pad group GRb may be the same or different. For instance, in FIG. 2, the distance Dm between two main-portion pads BDm in the main-portion pad group GRm may be less than the distance Db1 between two curving-portion pads BDb in the curving-portion pad group GRb or the distance Db2 between two curving-portion pads BDb in the curving-portion pad group GRb, but not limited thereto. Through the design of these distances, the position of the curving-portion pad BDb may avoid the region with the maximum curvature in the curve portion 114 of the flexible substrate 110.

Furthermore, a distance between two curving-portion pads BDb in one curving-portion pad group GRb may be the same or different from a distance between two curving-portion pads BDb in another curving-portion pad group GRb. For instance, in FIG. 2, since the available disposing space of the curving-portion pad BDb is decreased as the curving-portion pad BDb approaches the edge of the flexible substrate 110, the distance Db1 between two curving-portion pads BDb1 and BDb2 in the first curving-portion pad group GRb1 may be greater than the distance Db2 between two curving-portion pads BDb3 and BDb4 in the second curving-portion pad group GRb2 in the condition that a distance between the first curving-portion pad group GRb1 and the edge of the flexible substrate 110 is greater than a distance between the second curving-portion pad group GRb2 and the edge of the flexible substrate 110, but not limited thereto.

In the present disclosure, an area (size) of the electronic unit 120 and an area (size) of the pad BD may be designed based on requirement(s), and the area (size) of the electronic unit 120 may be related to or not be related to the area (size) of the pad BD. In the present disclosure, the area (size) of the main-portion electronic unit 122 may be the same as or different from the area (size) of the curving-portion electronic unit 124, and the area (size) of the main-portion pad BDm may be the same as or different from the area (size) of the curving-portion pad BDb. For instance, in FIG. 2 and FIG. 3, the area of the main-portion electronic unit 122 may be less than the area of the curving-portion electronic unit 124 (i.e., the main-portion electronic unit 122 is smaller so that the resolution of the display image in the main portion 112 is higher, and the curving-portion electronic unit 124 is bigger so that the bonding yield rate is improved), and the area of the main-portion pad BDm may be the same as the area of the curving-portion pad BDb, but not limited thereto. For instance (not shown in figures), the area of the main-portion electronic unit 122 may be the same as the area of the curving-portion electronic unit 124, and the area of the main-portion pad BDm may be the same as the area of the curving-portion pad BDb, but not limited thereto. Note that the area (size) of the electronic unit 120 and the area (size) of the pad BD are measured in the condition that the flexible substrate 110 is in the fully flat state.

In the present disclosure, the electronic device ED1 may further include other required film(s) and/or component(s). In some embodiments (as shown in FIG. 3), the electronic device ED1 may optionally include a pixel defining layer PDL disposed on the circuit layer 130, wherein the pixel defining layer PDL may be disposed between two electronic units 120 in the top view to separate these two electronic units 120. For example, the pixel defining layer PDL may include insulating material (e.g., organic insulating material or inorganic insulating material), other suitable material(s) or a combination thereof, but not limited thereto.

In some embodiments (as shown in FIG. 3), the electronic device ED1 may optionally include insulating layers PL1, PL2 and PL3 disposed on the electronic unit 120 and the circuit layer 130 and stacked in sequence. For instance, the insulating layer PL1 may cover and/or encapsulate the electronic unit 120 for protecting the electronic unit 120, and the insulating layers PL2 and PL3 may be flat layers for providing flat surfaces, but not limited thereto. For instance, the insulating layers PL1, PL2 and PL3 may include the same insulating material or different insulating materials (e.g., organic insulating material or inorganic insulating material), but not limited thereto.

In some embodiments (as shown in FIG. 3), the electronic device ED1 may optionally include light shielding layers 142 and 144 disposed on the electronic unit 120 and the circuit layer 130, wherein the light shielding layers 142 and 144 may be configured to shield some components to improve the quality of the electronic device ED1 (e.g., the light shielding layers 142 and 144 may shield a region with poor displaying effect, so as to enhance the displaying quality of the electronic device ED1). In FIG. 3, the light shielding layers 142 and 144 may be disposed between two electronic units 120 in the top view to separate these two electronic units 120. For example, the light shielding layers 142 and 144 may include metal, photoresist, ink, resin, pigment, other suitable light blocking material(s) or a combination thereof, but not limited thereto.

In some embodiments (as shown in FIG. 3), the electronic device ED1 may optionally include a color converting layer 150 disposed on the electronic unit 120 and the circuit layer 130, wherein the color converting layer 150 may be configured to adjust the color of the light emitted from the electronic unit 120. In FIG. 3, the color converting layer 150 may overlap the electronic unit 120 in the direction Z. For instance, the color converting layer 150 may include color filter, fluorescence material, phosphorescence material, QD material, other suitable material(s) or a combination thereof.

In some embodiments (as shown in FIG. 3), the electronic device ED1 may optionally include a covering layer 170 and a functional layer 160 disposed on the electronic unit 120 and the circuit layer 130, wherein the functional layer 160 may provide any suitable function. For instance, the covering layer 170 may include glass, quartz, ceramic, sapphire, polymer (e.g., PI, PET, PMMA, etc.), other suitable materials or a combination thereof. For instance, the functional layer 160 may provide an anti-reflective function (e.g., the functional layer 160 may include an anti-reflective layer), an adhering function (e.g., the functional layer 160 may include an adhering layer) or other suitable function.

In some embodiments (as shown in FIG. 3), the electronic device ED1 may optionally include a sensing structure 180 disposed on the electronic unit 120 and the circuit layer 130 (e.g., the sensing structure 180 may be disposed between the electronic unit 120 and the covering layer 170), wherein the sensing structure 180 may be configured to perform required sensing. For instance, the sensing structure 180 may be configured to perform a touch sensing, a fingerprint sensing, a light sensing, other required sensing or a combination thereof. For example, the sensing structure 180 may include a sensing component 182 (e.g., a sensing electrode) and an insulating structure 184, wherein the sensing component 182 may have a sensing function, but not limited thereto.

The electronic device of the present disclosure is not limited to the above embodiments. Further embodiments of the present disclosure are described below. For ease of comparison, same components will be labeled with the same symbol in the following. The following descriptions relate the differences between each of the embodiments, and repeated parts will not be redundantly described.

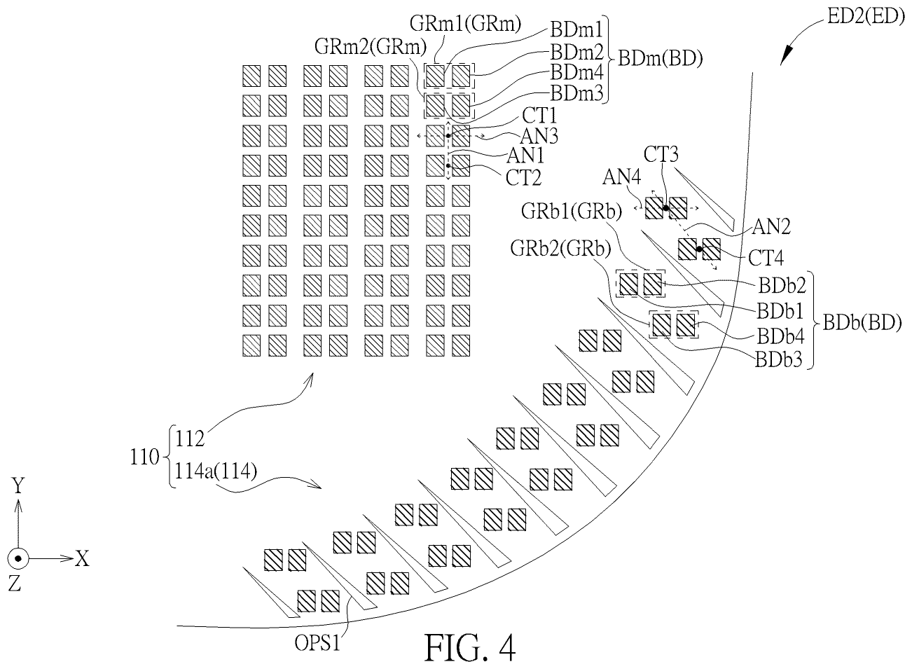

Referring to FIG. 4, FIG. 4 is a schematic diagram showing a top view of a flexible substrate and pads of an electronic device according to a second embodiment of the present disclosure, wherein FIG. 4 shows the flexible substrate 110 before bending (i.e., the flexible substrate 110 is in the fully flat state), and FIG. 4 shows a part of the main portion 112 and the corner region 114a of the curve portion 114. As shown in FIG. 4, a difference between this embodiment and the first embodiment is the design of the curving-portion pad BDb of the electronic device ED2. In FIG. 4, a rotating relation may not exist between the main-portion pad BDm and the curving-portion pad BDb. For instance, in FIG. 4, since the shape of the pad BD in the top view is a rectangle, the edges of the main-portion pad BDm may be respectively parallel to the direction X and the direction Y, and the edges of the curving-portion pad BDb may be respectively parallel to the direction X and the direction Y, but not limited thereto. In another aspect, the third axis AN3 crossing two centers of the main-portion pads BDm1 and BDm2 of the first main-portion pad group GRm1 may be parallel to the fourth axis AN4 crossing two centers of the curving-portion pads BDb1 and BDb2 of the first curving-portion pad group GRb1.

Although the third axis AN3 is parallel to the fourth axis AN4 in FIG. 4, since the main-portion pad groups GRm (or the main-portion pads BDm) are arranged in the direction X and the direction Y and the curving-portion pad groups GRb are substantially arranged in the extending direction of the first substrate opening OPS1, the first axis AN1 crossing the first center CT1 of the first main-portion pad group GRm1 and the second center CT2 of the second main-portion pad group GRm2 is not parallel to the second axis AN2 crossing the third center CT3 of the first curving-portion pad group GRb1 and the fourth center CT4 of the second curving-portion pad group GRb2.

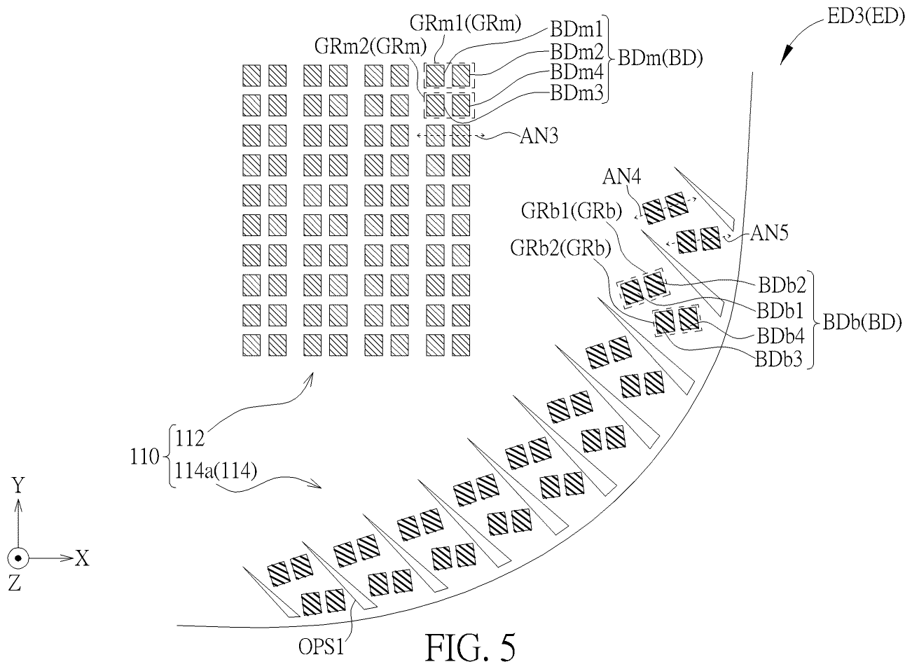

Referring to FIG. 5, FIG. 5 is a schematic diagram showing a top view of a flexible substrate and pads of an electronic device according to a third embodiment of the present disclosure, wherein FIG. 5 shows the flexible substrate 110 before bending (i.e., the flexible substrate 110 is in the fully flat state), and FIG. 5 shows a part of the main portion 112 and the corner region 114a of the curve portion 114. As shown in FIG. 5, a difference between this embodiment and the first embodiment is the design of the curving-portion pad BDb of the electronic device ED3. In FIG. 5, an arranging direction of the curving-portion pads BDb in one curving-portion pad group GRb may be different from an arranging direction of the curving-portion pads BDb in another curving-portion pad group GRb. For instance, in FIG. 5, the fourth axis AN4 crossing two centers of the curving-portion pads BDb1 and BDb2 of the first curving-portion pad group GRb1 may not be parallel to a fifth axis crossing two centers of the curving-portion pads BDb3 and BDb4 of the second curving-portion pad group GRb2, but not limited thereto. Namely, the curving-portion pads BDb of the electronic device ED3 may be arranged in a plurality of manners.

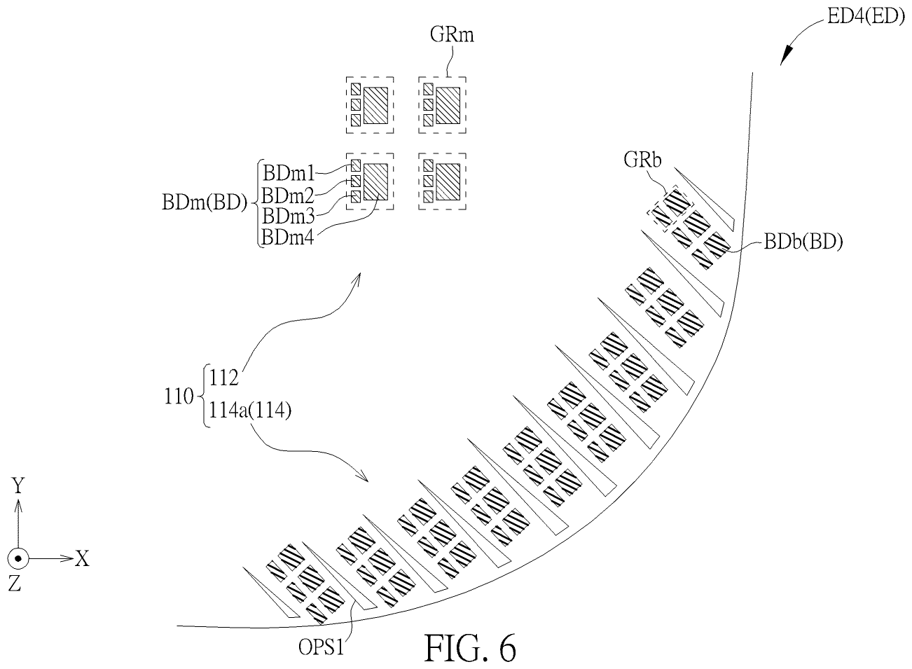

Referring to FIG. 6, FIG. 6 is a schematic diagram showing a top view of a flexible substrate and pads of an electronic device according to a fourth embodiment of the present disclosure, wherein FIG. 6 shows the flexible substrate 110 before bending (i.e., the flexible substrate 110 is in the fully flat state), and FIG. 6 shows a part of the main portion 112 and the corner region 114a of the curve portion 114. As shown in FIG. 6, a difference between this embodiment and the first embodiment is the design of the pad BD of the electronic device ED4. In FIG. 6, one main-portion pad group GRm may include four main-portion pads BDm1, BDm2, BDm3 and BDm4, and three main-portion electronic units 122 may be corresponding to one main-portion pad group GRm, wherein one main-portion electronic unit 122 may be bonded on the main-portion pads BDm1 and BDm4, another main-portion electronic unit 122 may be bonded on the main-portion pads BDm2 and BDm4, still another main-portion electronic unit 122 may be bonded on the main-portion pads BDm3 and BDm4 (i.e., three main-portion electronic units 122 may share the main-portion pad BDm4), and an area of the main-portion pad BDm4 may be greater than each of the areas of the main-portion pads BDm1, BDm2 and BDm3. For instance, electrodes electrically connected to the N-type semiconductor layers of the main-portion electronic units 122 may be bonded on the main-portion pad BDm4, and the electrodes electrically connected to the P-type semiconductor layers of the main-portion electronic units 122 may be bonded on the main-portion pads BDm1, BDm2 and BDm3 respectively, but not limited thereto. For instance, the main-portion pads BDm1, BDm2 and BDm3 may be disposed on a side of the main-portion pad BDm4, but not limited thereto. In this design, the total area of the main-portion pads BDm may be reduced, so as to increase the density of the main-portion electronic units 122 and/or decrease the size of the electronic device ED4.

On the other hand, as shown in FIG. 6, the curving-portion electronic units 124 may not share the curving-portion pad BDb, and the area of the main-portion pad BDm4 may be greater than the area of the curving-portion pad BDb, such that the curving-portion pad BDb may be easily avoid the region with the maximum curvature in the curve portion 114 of the flexible substrate 110.

In some embodiments, if three electronic units 120 are respectively configured to generate the red light, the green light and the blue light, a pixel in the main portion 112 may include three main-portion electronic units 122 corresponding to the same main-portion pad group GRm (these three main-portion electronic units 122 respectively generate the red light, the green light and the blue light), and a pixel in the curve portion 114 may include three adjacent curving-portion electronic units 124 respectively generate the red light, the green light and the blue light (i.e., the pixel in the curve portion 114 may include three adjacent curving-portion pad groups GRb). In this condition, a number of the main-portion pads BDm (e.g., four main-portion pads BDm) of the pixel in the main portion 112 may be less than a number of the curving-portion pads BDb (e.g., six curving-portion pads BDb) of the pixel in the curve portion 114.

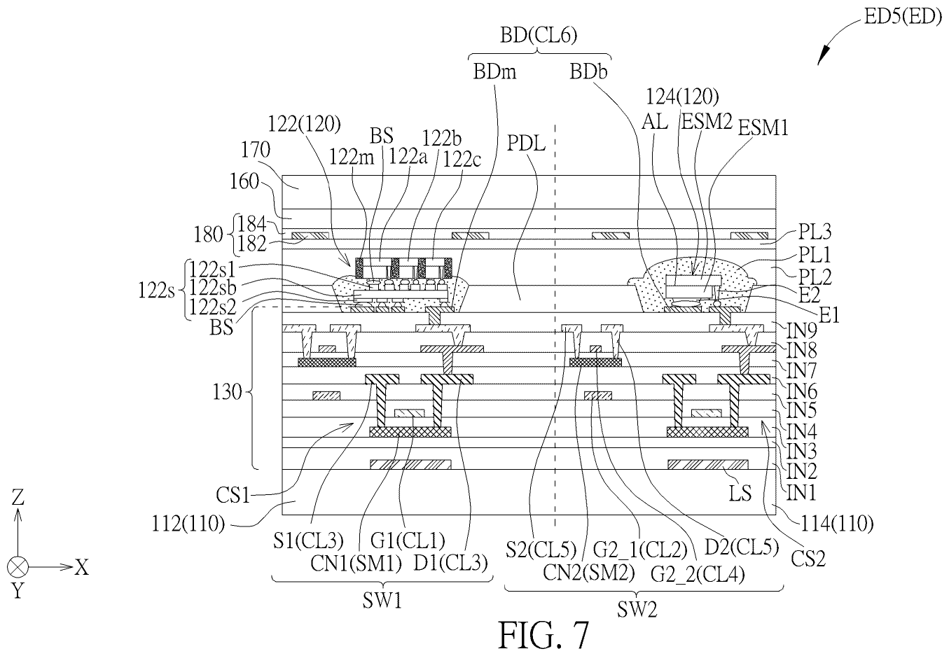

Referring to FIG. 7, FIG. 7 is a schematic diagram showing a cross-sectional view of an electronic device according to the fifth embodiment of the present disclosure. As shown in FIG. 7, a difference between this embodiment and the first embodiment is the design of the electronic unit 120 of the electronic device ED5. In FIG. 7, the main-portion electronic unit 122 may include an integrated light emitting chip having light emitting elements 122a, 122b and 122c respectively generating the red light, the green light and the blue light (in FIG. 7, the light emitting elements 122a, 122b and 122c are disposed in a molding layer 122m of the integrated light emitting chip). Namely, the pixel in the main portion 112 may include this integrated light emitting chip, and the curving-portion electronic units 124 may still respectively generate the red light, the green light and the blue light to make the pixel in the curve portion 114 include three adjacent curving-portion electronic units 124 respectively generating the red light, the green light and the blue light. Since the pixel in the curve portion 114 has three separated curving-portion electronic units 124, the curving-portion pads BDb and the curving-portion electronic units 124 may easily avoid the region with the maximum curvature in the curve portion 114 of the flexible substrate 110.

In the present disclosure, light-emitting areas of the light emitting elements 122a, 122b and 122c in the integrated light emitting chip may be designed based on requirement(s). In some embodiments, the light-emitting areas of the light emitting elements 122a, 122b and 122c in the integrated light emitting chip may be the same or different. For instance, the light-emitting area of the light emitting element 122a generating the red light may be greater than the light-emitting area of the light emitting element 122b generating the green light and the light-emitting area of the light emitting element 122c generating the blur light, but not limited thereto. In some embodiments, the light-emitting areas of the light emitting elements 122a, 122b and 122c in the integrated light emitting chip may be the same as or different from a light-emitting area of the curving-portion electronic unit 124. For instance, the light-emitting areas of the light emitting elements 122a, 122b and 122c in the integrated light emitting chip may be respectively less than the light-emitting areas of the curving-portion electronic units 124 respectively generating the red light, the green light and the blue light, but not limited thereto.

Furthermore, if the main-portion electronic unit 122 includes the integrated light emitting chip, the main-portion electronic unit 122 may optionally include a circuit structure 122s, wherein the integrated light emitting chip may be bonded on circuit pads 122s1 of the circuit structure 122s through bonding components BS, circuit pads 122s2 of the circuit structure 122s may be bonded on the main-portion pads BDm through bonding components BS, and the circuit pads 122s1 and 122s2 may be disposed on a circuit board 122sb. Due the existence of the circuit structure 122s, some pins of the integrated light emitting chip may be electrically connected to the same main-portion pad BDm, so as to decrease the number of the main-portion pads BDm. Also, even if the design of the main-portion pads BDm in the main-portion pad group GRm is changed, the integrated light emitting chip of the main-portion electronic unit 122 may be electrically connected to the corresponding main-portion pads BDm through the circuit structure 122s still. For example, if the main-portion electronic unit 122 including the integrated light emitting chip is applied to the main-portion pad group GRm shown in FIG. 6 (i.e., the main-portion pad group GRm includes four main-portion pads BDm1, BDm2, BDm3 and BDm4, and the light emitting elements 122a, 122b and 122c of the integrated light emitting chip share the main-portion pad BDm4), through the design of the circuit structure 122s, the light emitting element 122a generating the red light may be electrically connected to the main-portion pads BDm1 and BDm4, the light emitting element 122b generating the green light may be electrically connected to the main-portion pads BDm2 and BDm4, and the light emitting element 122c generating the blue light may be electrically connected to the main-portion pads BDm3 and BDm4, but not limited thereto.

Moreover, in some embodiments (not shown in figures), the curving-portion electronic unit 124 may also include an integrated light emitting chip having light emitting elements respectively generating the red light, the green light and the blue light, such that the pixel of the curve portion 114 may include this integrated light emitting chip. In some embodiments (not shown in figures), if the curving-portion electronic unit 124 includes the integrated light emitting chip, pins of the integrated light emitting chip of the curving-portion electronic unit 124 may not share the curving-portion pad BDb (e.g., the design of the curving-portion pads BDb shown in FIG. 6). Therefore, a number of the pins of the integrated light emitting chip of the curving-portion electronic unit 124 may be the same as a number of the corresponding curving-portion pads BDb, such that the curving-portion pads BDb may easily avoid the region with the maximum curvature in the curve portion 114 of the flexible substrate 110.

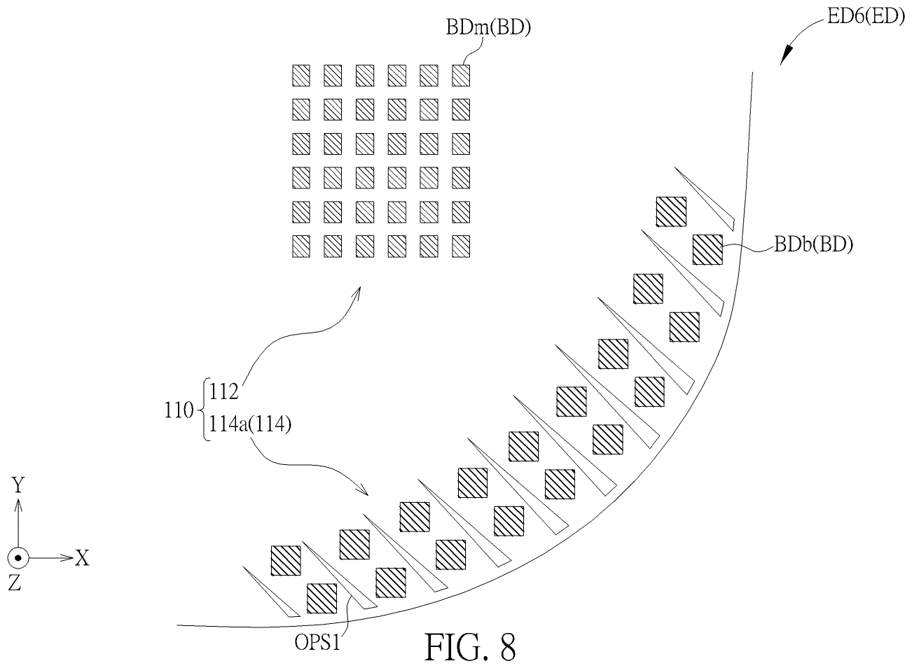

Referring to FIG. 8, FIG. 8 is a schematic diagram showing a top view of a flexible substrate and pads of an electronic device according to a sixth embodiment of the present disclosure, wherein FIG. 8 shows the flexible substrate 110 before bending (i.e., the flexible substrate 110 is in the fully flat state), and FIG. 8 shows a part of the main portion 112 and the corner region 114a of the curve portion 114. For example, the electronic unit 120 of the electronic device ED6 shown in FIG. 8 is a vertical type light emitting unit (i.e., the semiconductor layers of the electronic unit 120 are between two electrodes in the direction Z), such that the pad BD shown in FIG. 8 is corresponding to the electronic unit 120 which is the vertical type light emitting unit.

As shown in FIG. 8, a difference between this embodiment and the first embodiment is the design of the pad BD of the electronic device ED6. In FIG. 8, the area (size) of the main-portion pad BDm may be different from the area (size) of the curving-portion pad BDb. Namely, a ratio of the area (size) of the main-portion pad BDm to the area (size) of the curving-portion pad BDb may not be equal to 1. For instance, the area of the main-portion pad BDm may be less than the area of the curving-portion pad BDb, such that the ratio of the area of the main-portion pad BDm to the area of the curving-portion pad BDb may be less than 1, but not limited thereto. For instance, the ratio of the area of the main-portion pad BDm to the area of the curving-portion pad BDb may be greater than or equal to 0.3 and less than 1, but not limited thereto.

Moreover, the area (size) of the electronic unit 120 may be designed based on requirement(s), and the area (size) of the electronic unit 120 may be related to or not be related to the area (size) of the pad BD. In some embodiments (as shown in FIG. 8), the area of the main-portion pad BDm may be less than the area of the curving-portion pad BDb, and the area of the main-portion electronic unit 122 may be the same as or different from the area of the curving-portion electronic unit 124. For example, the area of the main-portion pad BDm may be less than the area of the curving-portion pad BDb, and the area of the main-portion electronic unit 122 may be less than the area of the curving-portion electronic unit 124, but not limited thereto.

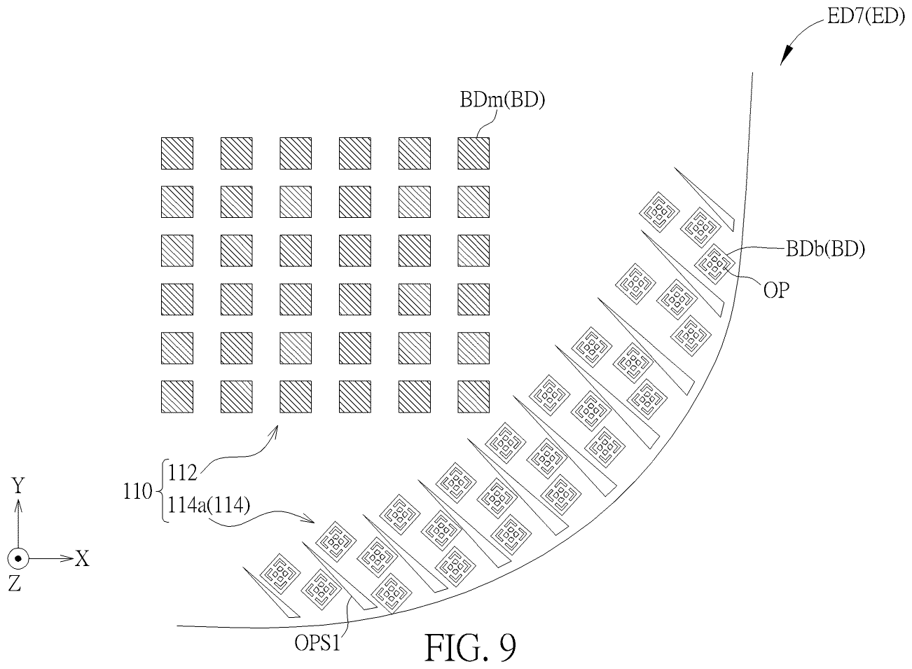

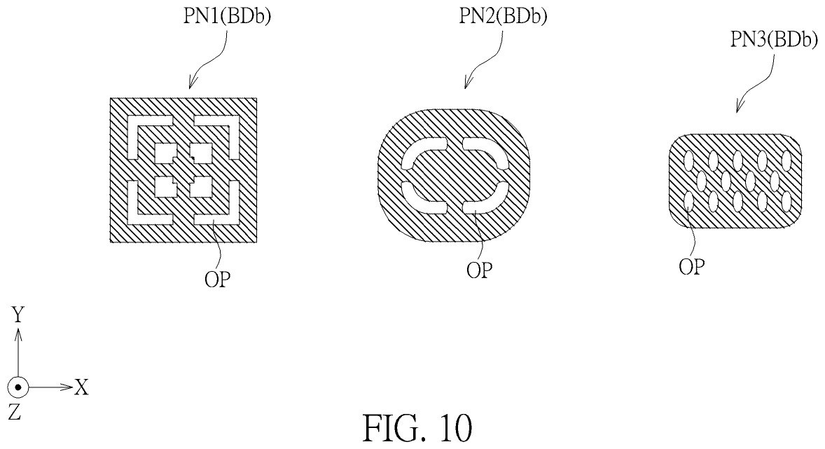

Referring to FIG. 9 and FIG. 10, FIG. 9 is a schematic diagram showing a top view of a flexible substrate and pads of an electronic device according to a seventh embodiment of the present disclosure, and FIG. 10 is a schematic diagram showing a top view of designs of a curving-portion pad of an electronic device according to the seventh embodiment of the present disclosure, wherein FIG. 9 shows the flexible substrate 110 before bending (i.e., the flexible substrate 110 is in the fully flat state), and FIG. 9 shows a part of the main portion 112 and the corner region 114a of the curve portion 114. As shown in FIG. 9, a difference between this embodiment and the sixth embodiment (FIG. 8) is the design of the curving-portion pad BDb of the electronic device ED7. In FIG. 9 and FIG. 10, the curving-portion pad BDb may include a plurality of openings OP for releasing the stress (e.g., the stress caused by bending the curve portion 114). For example, in FIG. 9, each curving-portion pad BDb may include a plurality of openings OP (e.g., the curving-portion pad BDb shown in FIG. 9 may use a first designing pattern PN1 shown in FIG. 10), but not limited thereto.

For instance, in the first designing pattern PN1 of the curving-portion pad BDb in FIG. 10, an outmost outline of the curving-portion pad BDb is a rectangle, and the opening OP of the curving-portion pad BDb is L-shaped, wherein the openings OP may be arranged in a ring, but not limited thereto. For instance, in a second designing pattern PN2 of the curving-portion pad BDb shown in FIG. 10, an outmost outline of the curving-portion pad BDb may be a rectangle with curved chamfers (e.g., arcs), and the opening OP of the curving-portion pad BDb may have a plurality of curved edges, wherein the opening OP may be arranged in a ring, but not limited thereto. For instance, in a third designing pattern PN3 of the curving-portion pad BDb in FIG. 10, an outmost outline of the curving-portion pad BDb may be a rectangle with curved chamfers (e.g., arcs), and the opening OP of the curving-portion pad BDb may be an oval, wherein the opening OP may be arranged in a plurality of rows, but not limited thereto.

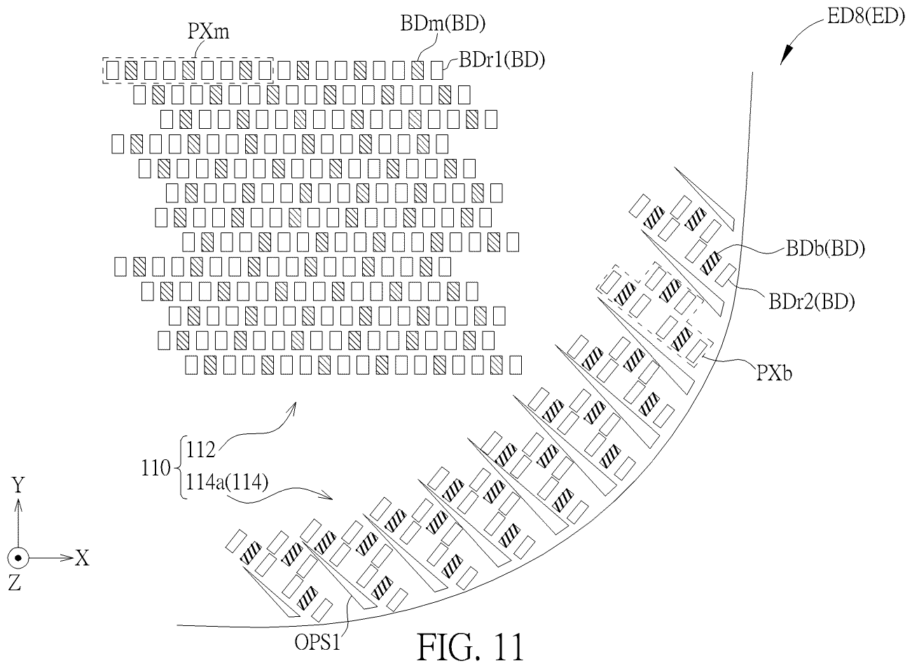

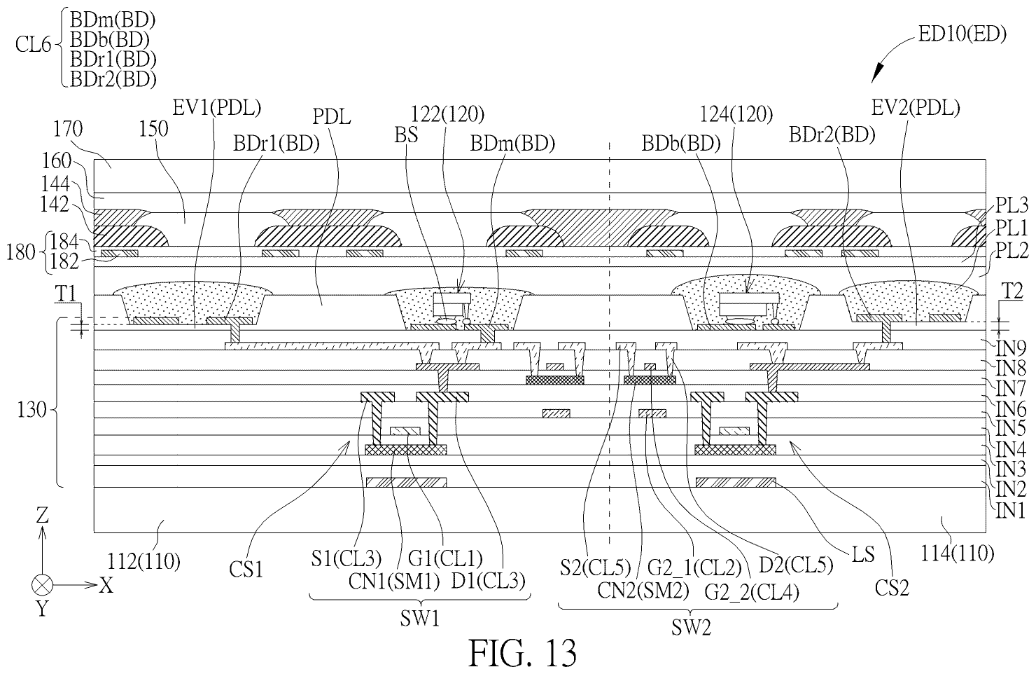

Referring to FIG. 11, FIG. 11 is a schematic diagram showing a top view of a flexible substrate and pads of an electronic device according to an eighth embodiment of the present disclosure, wherein FIG. 11 shows the flexible substrate 110 before bending (i.e., the flexible substrate 110 is in the fully flat state), and FIG. 11 shows a part of the main portion 112 and the corner region 114a of the curve portion 114. As shown in FIG. 11, a difference between this embodiment and the sixth embodiment (FIG. 8) is that the pads BD of the electronic device ED8 further include a plurality of first redundant pads BDr1 and a plurality of second redundant pads BDr2, wherein the first redundant pad BDr1 is disposed on the main portion 112 of the flexible substrate 110 and electrically connected to the first circuit CS1 (i.e., the main-portion pad BDm and the first redundant pad BDr1 are electrically connected to the first circuit CS1, and this relation is shown in FIG. 13), and the second redundant pad BDr2 is disposed on the curve portion 114 of the flexible substrate 110 and electrically connected to the second circuit CS2 (i.e., the curving-portion pad BDb and the second redundant pad BDr2 are electrically connected to the second circuit CS2, and this relation is shown in FIG. 13). In FIG. 11, the first redundant pad BDr1 may be adjacent to the main-portion pad BDm, and the second redundant pad BDr2 may be adjacent to the curving-portion pad BDb. For instance, the main-portion pad BDm may be disposed between two first redundant pads BDr1, and the curving-portion pad BDb may be disposed between two second redundant pads BDr2, but not limited thereto.

In the present disclosure, if the main-portion electronic unit 122 disposed on the main-portion pad BDm does not meet the requirement(s) (e.g., the main-portion electronic unit 122 may have an appearance defect, a color deviation, etc.) or is not be operated normally (e.g., abnormal operation may be caused by a positional deviation, a poor bonding, etc.), a main-portion repairing electronic unit configured to repair the main portion 112 may be disposed on the first redundant pad BDr1 adjacent to this main-portion pad BDm, so as to achieve the repairing effect. Similarly, if the curving-portion electronic unit 124 disposed on the curving-portion pad BDb does not meet the requirement(s) (e.g., the curving-portion electronic unit 124 may have an appearance defect, a color deviation, etc.) or is not be operated normally (e.g., abnormal operation may be caused by a positional deviation, a poor bonding, etc.), a curving-portion repairing electronic unit configured to repair the curve portion 114 may be disposed on the second redundant pad BDr2 adjacent to this curving-portion pad BDb, so as to achieve the repairing effect. In addition, the first redundant pad BDr1 and the second redundant pad BDr2 may serve as alignment marks in the manufacturing process of the electronic device ED8 (e.g., a transfer process of the electronic unit 120).

In the present disclosure, a number of the first redundant pads BDr1 and a number of the second redundant pads BDr2 may be designed based on requirement(s), and a ratio of the number of the first redundant pads BDr1 to the number of the main-portion pads BDm and a ratio of the number of the second redundant pads BDr2 to the number of the curving-portion pads BDb may be designed based on requirement(s). For instance, in FIG. 11, if the pixel PXm in the main portion 112 includes three main-portion electronic units 122 (these main-portion electronic units 122 are respectively configured to generate the red light, the green light and the blue light), the pixel PXm of the main portion 112 may include three main-portion pads BDm and six first redundant pads BDr1; if the pixel PXb in the curve portion 114 includes three curving-portion electronic units 124 (these curving-portion electronic units 124 are respectively configured to generate the red light, the green light and the blue light), the pixel PXb of the curve portion 114 may include three curving-portion pads BDb and six second redundant pads BDr2. Thus, a ratio of the number of the first redundant pads BDr1 to the number of the main-portion pads BDm may be the same as a ratio of the number of the second redundant pads BDr2 to the number of the curving-portion pads BDb, and the number of the first redundant pad BDr1 of one pixel PXm in the main portion 112 may be the same as the number of the second redundant pad BDr2 of one pixel PXb in the curve portion 114, but not limited thereto.

In the present disclosure, the area (size) of the first redundant pad BDr1 and the area (size) of the second redundant pad BDr2 may be designed based on requirement(s), such that the area of the first redundant pad BDr1 may be the same as or different from the area of the second redundant pad BDr2. For instance, in FIG. 11, the area of the main-portion pad BDm may be less than the area of the curving-portion pad BDb, the area of the first redundant pad BDr1 may be the same as the area of the main-portion pad BDm, and the area of the second redundant pad BDr2 may be the same as the area of the curving-portion pad BDb. Therefore, the area of the first redundant pad BDr1 may be less than the area of the second redundant pad BDr2, but not limited thereto.

Moreover, the first redundant pad BDr1 and the second redundant pad BDr2 may optionally have different shapes in the top view. In some embodiments, the second redundant pad BDr2 may include a plurality of openings for releasing the stress (e.g., the stress caused by bending the curve portion 114). For example, the pattern design of the second redundant pad BDr2 may be referred to the first designing pattern PN1, the second designing pattern PN2 and the third designing pattern PN3 shown in FIG. 10, and these parts will not be redundantly described.

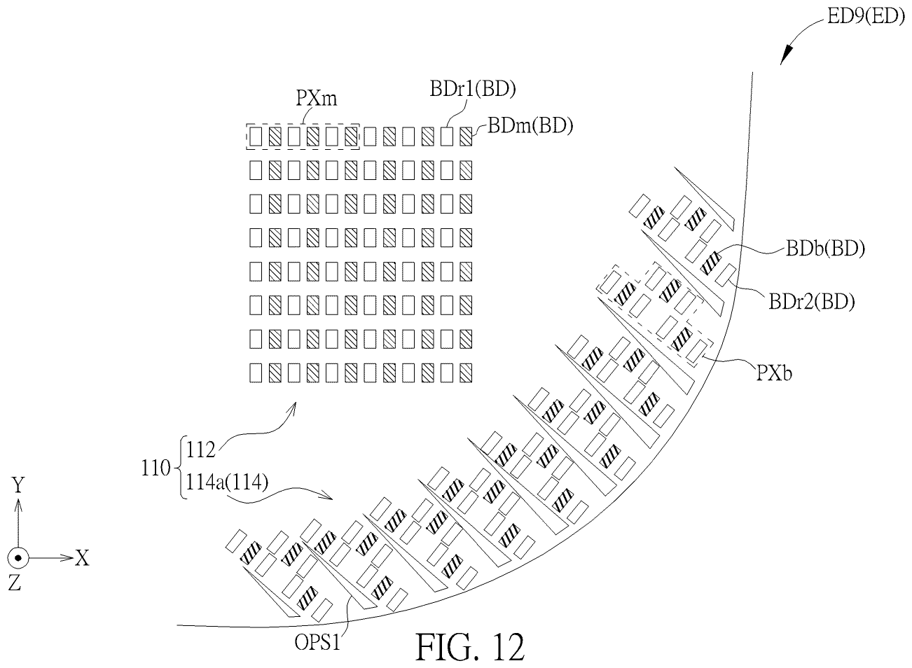

Referring to FIG. 12, FIG. 12 is a schematic diagram showing a top view of a flexible substrate and pads of an electronic device according to a ninth embodiment of the present disclosure, wherein FIG. 12 shows the flexible substrate 110 before bending (i.e., the flexible substrate 110 is in the fully flat state), and FIG. 12 shows a part of the main portion 112 and the corner region 114a of the curve portion 114. As shown in FIG. 12, a difference between this embodiment and the eighth embodiment (FIG. 11) is the number of the first redundant pads BDr1 and the number of the second redundant pads BDr2 of the electronic device ED9. For example, in FIG. 12, if the pixel PXm of the main portion 112 includes three main-portion electronic units 122 (these main-portion electronic units 122 are respectively configured to generate the red light, the green light and the blue light), the pixel PXm in the main portion 112 may include three main-portion pads BDm and three first redundant pads BDr1; if the pixel PXb in the curve portion 114 includes three curving-portion electronic units 124 (these curving-portion electronic units 124 are respectively configured to generate the red light, the green light and the blue light), the pixel PXb in the curve portion 114 may include three curving-portion pads BDb and six second redundant pads BDr2. Thus, a ratio of the number of the second redundant pads BDr2 to the number of the curving-portion pads BDb may be greater than a ratio of the number of the first redundant pads BDr1 to the number of the main-portion pads BDm, and the number of the second redundant pads BDr2 of one pixel PXb in the curve portion 114 may be greater than the number of the first redundant pads BDr1 of one pixel PXm in the main portion 112, but not limited thereto.

Referring to FIG. 13, FIG. 13 is a schematic diagram showing a cross-sectional view of an electronic device according to a tenth embodiment of the present disclosure. As shown in FIG. 13, differences between this embodiment and the eighth embodiment (FIG. 11) are the designs of the first redundant pad BDr1 and the second redundant pad BDr2 of the electronic device ED10. In FIG. 13, a top surface of the first redundant pad BDr1 and a top surface of the second redundant pad BDr2 may be higher than a top surface of the main-portion pad BDm and a top surface of the curving-portion pad BDb in the direction Z. Therefore, in the repairing process of the electronic device ED10 which bonds the main-portion repairing electronic unit on the first redundant pad BDr1 and/or bonds the curving-portion repairing electronic unit on the second redundant pad BDr2, the damage possibilities of the main-portion electronic unit 122 and the curving-portion electronic unit 124 in the repairing process is decreased (e.g., crushing damages on the main-portion electronic unit 122 and the curving-portion electronic unit 124 are decreased or avoided). In some embodiments (as shown in FIG. 13), compared with the main-portion pad BDm and the curving-portion pad BDb, the first redundant pad BDr1 and the second redundant pad BDr2 may be respectively heightened by a first heightening part EV1 and a second heightening part EV2 including an insulating material in the cross-sectional view. For example, in FIG. 13, the first heightening part EV1 and the second heightening part EV2 may belong to the pixel defining layer PDL, such that the first redundant pad BDr1 and the second redundant pad BDr2 may be heightened by the pixel defining layer PDL, wherein the first heightening part EV1 may be disposed between the first redundant pad BDr1 and the insulating layer IN9, the second heightening part EV2 may be disposed between the second redundant pad BDr2 and the insulating layer IN9, and the pixel defining layer PDL may not be disposed between the main-portion pad BDm and the insulating layer IN9 and not be disposed between the curving-portion pad BDb and the insulating layer IN9 (e.g., the main-portion pad BDm and the curving-portion pad BDb may be directly in contact with the insulating layer IN9), but not limited thereto.

Furthermore, a thickness T1 of the first heightening part EV1 and a thickness T2 of the second heightening part EV2 may be the same or different based on requirement(s). For instance, in FIG. 13, the thickness T1 of the first heightening part EV1 may be less than the thickness T2 of the second heightening part EV2, but not limited thereto.

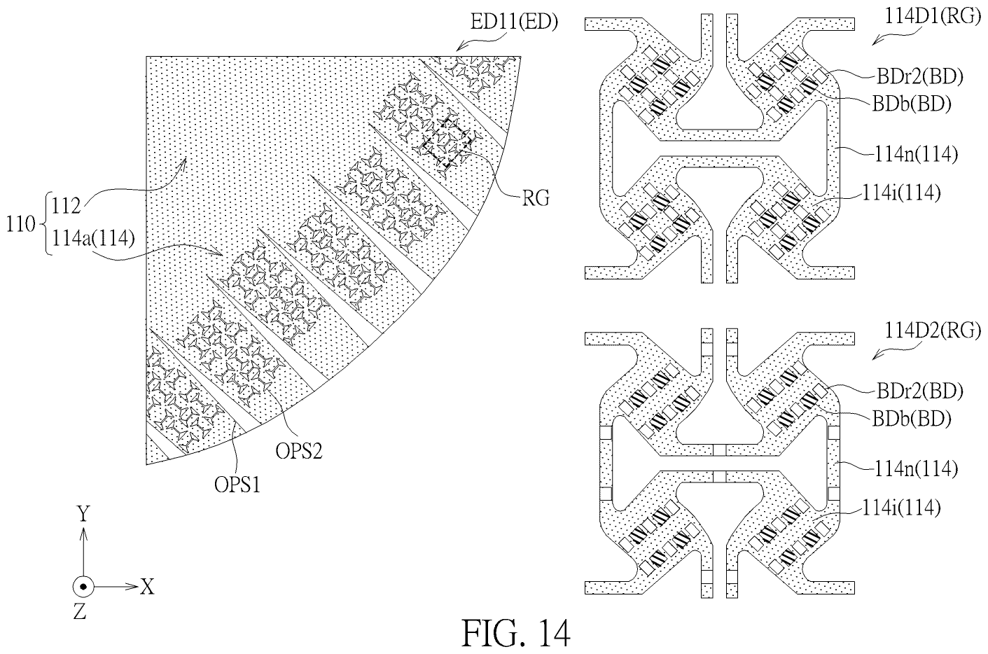

Referring to FIG. 14, FIG. 14 is a schematic diagram showing a top view of a flexible substrate, pads and designs of a curve portion of an electronic device according to an eleventh embodiment of the present disclosure, wherein FIG. 14 shows the flexible substrate 110 before bending (i.e., the flexible substrate 110 is in the fully flat state), FIG. 14 shows a part of the main portion 112 and the corner region 114a of the curve portion 114, and a first design 114D1 and a second design 114D2 of the curve portion 114 is an enlarged figure of a region RG. As shown in FIG. 14, a difference between this embodiment and the eighth embodiment (FIG. 11) is that the curve portion 114 of the flexible substrate 110 of the electronic device ED11 has other patterning design. In some embodiments, the patterning design of the curve portion 114 may enhance a flexibility and/or a stretch ability of the curve portion 114 of the flexible substrate 110. In FIG. 14, the curve portion 114 of the flexible substrate 110 may further include a plurality of second substrate openings OPS2, such that the curve portion 114 of the flexible substrate 110 may have a plurality of island portions 114i a plurality of bridge portions 114n connected to the island portions 114i. For instance, in FIG. 14, the island portions 114i are separated from each other due to the existences of the second substrate openings OPS2, each island portion 114i may be connected to four bridge portions 114n, and the bridge portion 114n may be connected between two island portions 114i, but not limited thereto. For instance, each of the first design 114D1 and the second design 114D2 of the curve portion 114 shown in FIG. 14 shows one substrate unit, and this substrate unit includes four island portions 114i and twelve bridge portions 114n connected to each other, but not limited thereto.

In the present disclosure, the shape of the island portion 114i and the shape of the bridge portion 114n may be designed based on requirement(s), and the arrangement of the island portions 114i and the bridge portions 114n may be designed based on requirement(s). In some embodiments, each of the shape of the island portion 114i and the shape of the bridge portion 114n may be a polygon (e.g., rectangle), a shape with curved edge(s) (e.g., a circle, an oval) or other suitable shape. For instance, in FIG. 14, the island portion 114i may be a quadrilateral, and the bridge portion 114n may be a strip type structure, but not limited thereto. In some embodiments, an edge of a connection between the bridge portion 114n and the island portion 114i may be a curved edge (e.g., an arc), so as to enhance the yield rate of the curve portion 114 of the flexible substrate 110 when the curve portion 114 is stretched and/or deformed, but not limited thereto.

In the present disclosure, the second substrate opening OPS2 may have suitable shape and be arranged in suitable manner. For example, in FIG. 14, the second substrate opening OPS2 may be a H-shaped opening, but not limited thereto. For instance, in FIG. 14, a 90-degree rotating relation may exist between two adjacent second substrate openings OPS2, but not limited thereto.

Since the curve portion 114 of the flexible substrate 110 has the island portions 114i and the bridge portions 114n, when the curve portion 114 of the flexible substrate 110 is stretched and/or deformed by an external force, the island portion 114i may rotate, and the bridge portion 114n may be deformed, but not limited thereto.

In the first design 114D1 of the curve portion 114 shown in FIG. 14, the curving-portion pads BDb and the second redundant pads BDr2 may be disposed on the island portion 114i, such that the curving-portion electronic units 124 and the curving-portion repairing electronic units may be disposed on the island portion 114i, but not limited thereto. In the second design 114D2 of the curve portion 114 shown in FIG. 14, the curving-portion pads BDb may be disposed on the island portion 114i to make the curving-portion electronic units 124 be disposed on the island portion 114i, and the second redundant pads BDr2 may be disposed on the island portion 114i and the bridge portion 114n to make the curving-portion repairing electronic units be disposed on the island portion 114i and the bridge portion 114n, but not limited thereto.

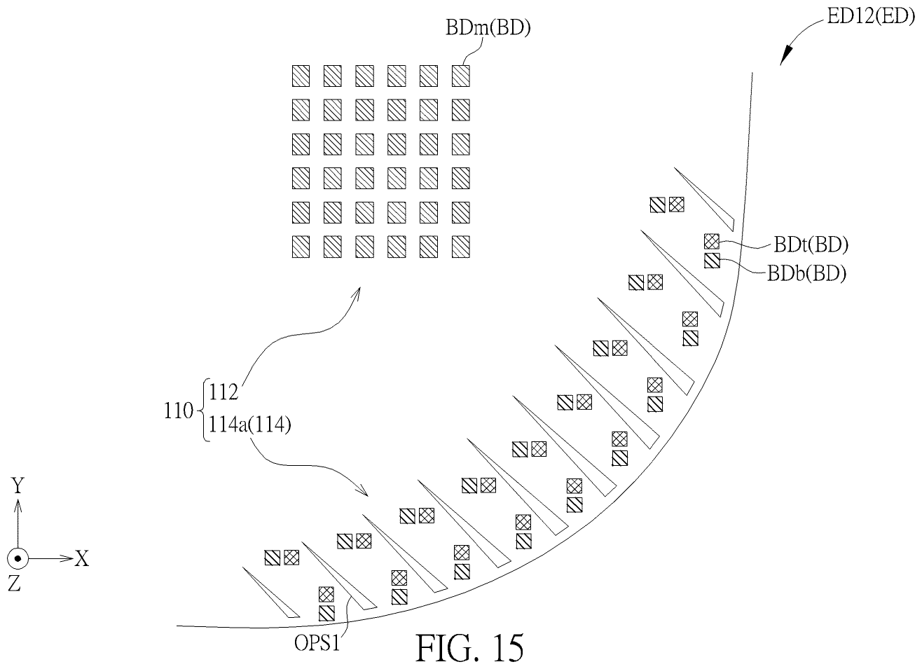

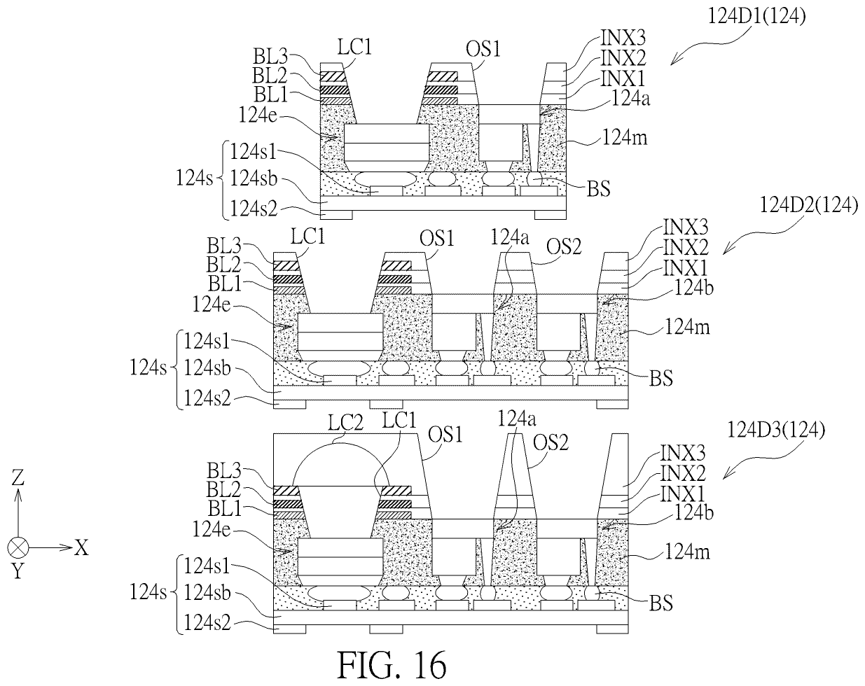

Referring to FIG. 15 and FIG. 16, FIG. 15 is a schematic diagram showing a top view of a flexible substrate and pads of an electronic device according to a twelfth embodiment of the present disclosure, and FIG. 16 is a schematic diagram showing a cross-sectional view of designs of a curving-portion electronic unit of an electronic device according to the twelfth embodiment of the present disclosure, wherein FIG. 15 shows the flexible substrate 110 before bending (i.e., the flexible substrate 110 is in the fully flat state), and FIG. 15 shows a part of the main portion 112 and the corner region 114a of the curve portion 114. As shown in FIG. 15, a difference between this embodiment and the sixth embodiment (FIG. 8) is the design of the pads BD of the electronic device ED12. In FIG. 15, the area (size) of the main-portion pad BDm may be greater than the area (size) of the curving-portion pad BDb, such that a ratio of the area (size) of the main-portion pad BDm to the area (size) of the curving-portion pad BDb may be greater than 1, but not limited thereto. For instance, a ratio of the area of the main-portion pad BDm to the area of the curving-portion pad BDb may be greater than 1 and less than 4, but not limited thereto.

Furthermore, the area (size) of the electronic unit 120 may be designed based on requirement(s), and the area (size) of the electronic unit 120 may be related to or not be related to the area (size) of the pad BD. In some embodiments (as shown in FIG. 15), the area of the main-portion pad BDm may be greater than the area of the curving-portion pad BDb, and the area of the main-portion electronic unit 122 may be the same as or different from the area of the curving-portion electronic unit 124. For instance, the area of the main-portion pad BDm may be greater than the area of the curving-portion pad BDb, and the area (e.g., the light-emitting area) of the main-portion electronic unit 122 may be greater than the area (e.g., the light-emitting area) of the curving-portion electronic unit 124, but not limited thereto.

As shown in FIG. 15 and FIG. 16, since the area of the curving-portion pad BDb and the area (e.g., the light-emitting area) of the curving-portion electronic unit 124 are smaller, other electronic component(s) may be optionally disposed on the curve portion 114 of the flexible substrate 110. For instance, in a structure 124D1 shown in FIG. 16, the electronic device ED12 may optionally include a sensor 124e disposed on the curve portion 114 and configured to perform a required sensing. For example, the sensor 124e may be configured to perform a light sensing, other required sensing or a combination thereof. For example, in the structure 124D1 shown in FIG. 16, the sensor 124e may be a light sensor and include a plurality of semiconductor layers, but not limited thereto. For example, in the structure 124D1 shown in FIG. 16, the curving-portion electronic unit 124 may be an integrated chip including the sensor 124e and the light emitting element 124a (in FIG. 16, the sensor 124e and the light emitting element 124a may be disposed in a molding layer 124m of the integrated chip), but not limited thereto. In some embodiments (e.g., the structure 124D shown in FIG. 16), in order to increase a light-sensing effect of the sensor 124e, a first light concentrating structure LC1 configured to concentrate the light may be disposed on the sensor 124e, wherein the first light concentrating structure LC1 may be formed by forming through holes in a plurality of insulating layers INX1, INX2 and INX3 and through holes in a plurality of light-shielding layers BL1, BL2 and BL3, and the insulating layers INX1, INX2 and INX3 and the light-shielding layers BL1, BL2 and BL3 may be stacked alternately in the direction Z. The light-shielding layers BL1, BL2 and BL3 may be configured to prevent light with a larger incident angle from entering the sensor 124e, thereby reducing noise sensed by the sensor 124e. In the structure 124D1 shown in FIG. 16, since the first light concentrating structure LC1 passes through the light-shielding layers BL1, BL2 and BL3, the light concentrating effect of the first light concentrating structure LC1 may be enhanced. Moreover, in order to prevent these insulating layers INX1, INX2 and INX3 from affecting the light emitted from the light emitting element 124a, an opening structure OS1 may be disposed on the light emitting element 124a, wherein the opening structure OS1 may be formed by forming through holes in the insulating layers INX1, INX2 and INX3.

For example, in a structure 124D2 shown in FIG. 16, the electronic device ED12 may further include an infrared light emitting element 124b configured to generate infrared light. For example, in the structure 124D2 shown in FIG. 16, the curving-portion electronic unit 124 may be an integrated chip including the sensor 124e, the light emitting element 124a and the infrared light emitting element 124b (in FIG. 16, the sensor 124e, the light emitting element 124a and the infrared light emitting element 124b may be disposed in a molding layer 124m of the integrated chip), and an opening structure OS2 may be disposed on the infrared light emitting element 124b, but not limited thereto. For example, in a structure 124D3 shown in FIG. 16, in order to enhance the light-sensing effect of the sensor 124e, a second light concentrating structure LC2 configured to concentrate the light may be disposed on the sensor 124e. For instance, the first light concentrating structure LC1 and the second light concentrating structure LC2 may overlap in the direction Z, but not limited thereto. For instance, the second light concentrating structure LC2 may be a lens (e.g., a convex lens), but not limited thereto.

In FIG. 15, the pads BD may further include a plurality of additional pads BDt disposed on the curve portion 114 of the flexible substrate 110, wherein the additional pad BDt may be configured to be electrically connected to other electronic component, such as the sensor 124e or the infrared light emitting element 124b, and provide a signal to this electronic component. For instance, in FIG. 15, the additional pad BDt may be adjacent to the curving-portion pad BDb, but not limited thereto.

For instance, if the curving-portion electronic unit 124 includes the integrated chip (e.g., the structure 124D1, 124D2 or 124D3 shown in FIG. 16) so as to include other electronic component(s) (such as the sensor 124e and/or the infrared light emitting element 124b), the curving-portion electronic unit 124 may optionally include a circuit structure 124s, wherein the integrated chip may be bonded on circuit pads 124s1 of the circuit structure 124s through bonding components BS, circuit pads 124s2 of the circuit structure 124s may be bonded on the additional pad(s) BDt and the curving-portion pad(s) BDb through bonding components BS, and the circuit pads 124s1 and 124s2 may be disposed on a circuit board 124sb, but not limited thereto. Due to the existence of the circuit structure 124s, some pins of the integrated chip may be electrically connected to the same pad BD on the curve portion 114, so as to decrease the number of the pads BD. Also, even if the design of the pads BD on the curve portion 114 is changed, the integrated chip of the curving-portion electronic unit 124 may be electrically connected to the corresponding pads BD through the circuit structure 124s still.

For example (not shown in figures), if the curving-portion electronic unit 124 includes the integrated chip so as to include other electronic component(s) (such as the sensor 124e and/or the infrared light emitting element 124b), the curving-portion electronic unit 124 may be directly bonded on the additional pad(s) BDt and the curving-portion pad(s) BDb, but not limited thereto. For example (not shown in figures), if other electronic component(s) (such as the sensor 124e and/or the infrared light emitting element 124b) is separated from the curving-portion electronic unit 124, other electronic component(s) (such as the sensor 124e and/or the infrared light emitting element 124b) may be directly bonded on the additional pad(s) BDt, but not limited thereto.

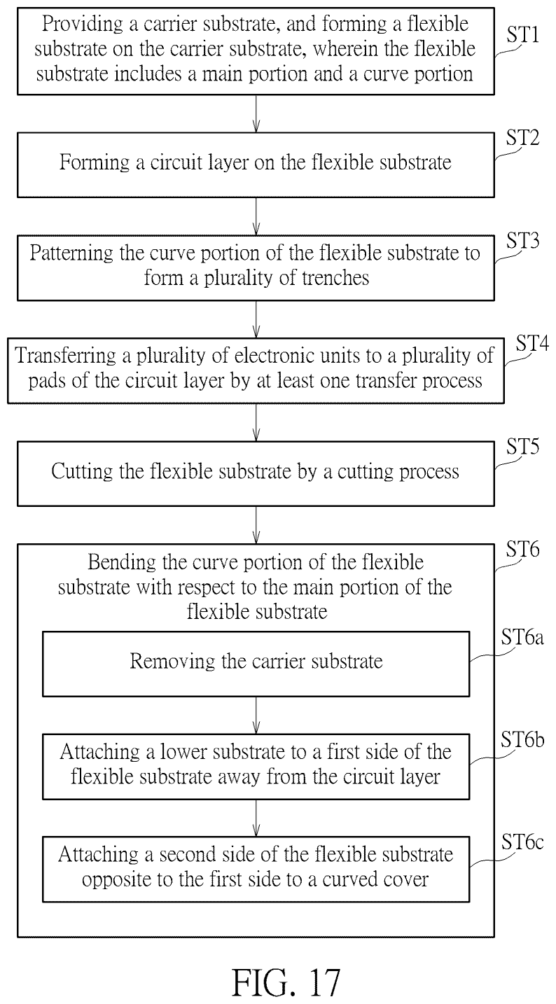

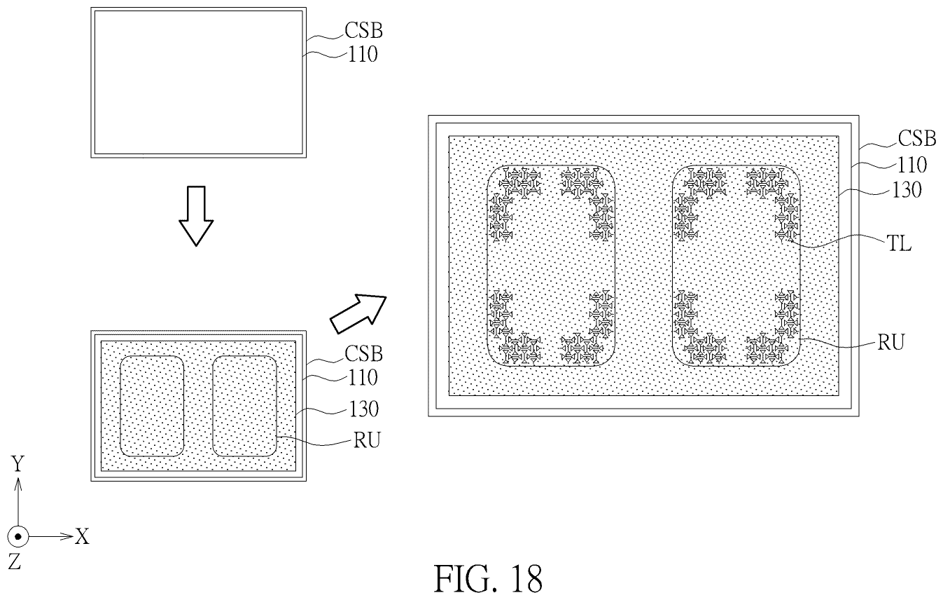

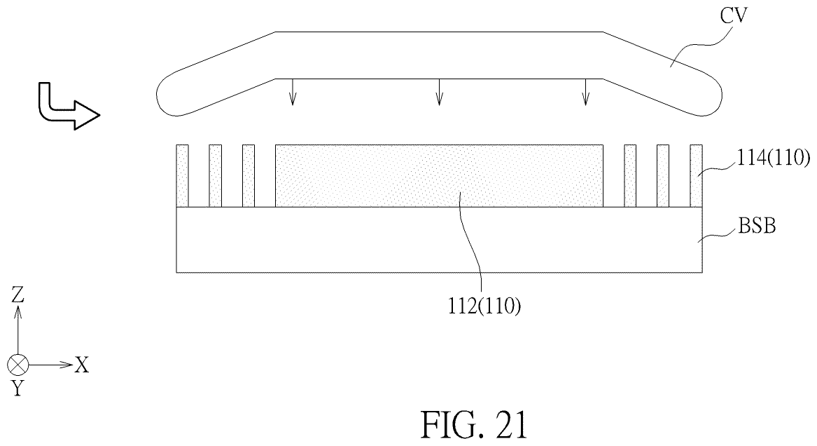

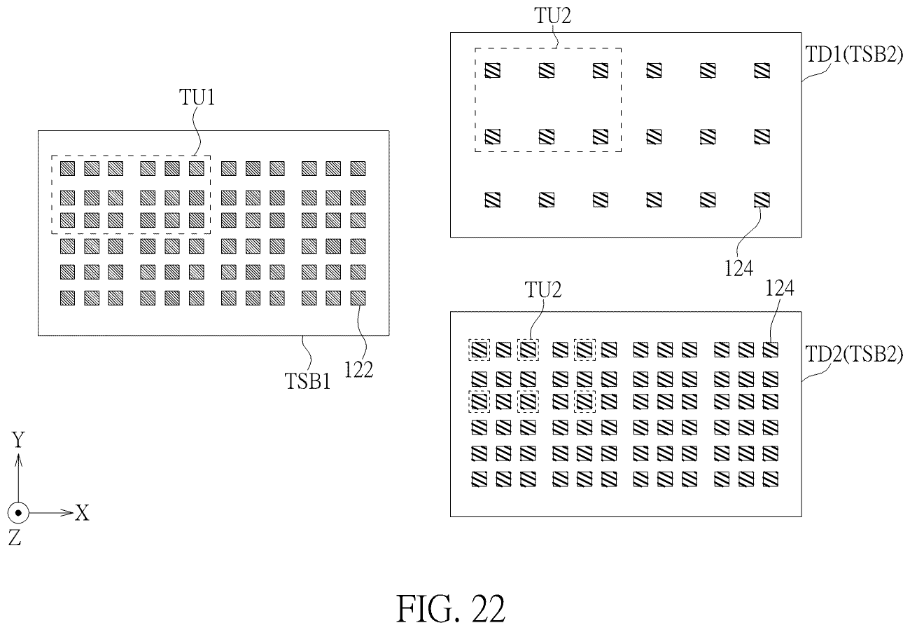

Referring to FIG. 17 to FIG. 22, FIG. 17 is a schematic diagram showing a flowchart of a method of manufacturing an electronic device according to an embodiment of the present disclosure, FIG. 18 to FIG. 21 are schematic diagrams showing structures at different steps of a method of manufacturing an electronic device according to an embodiment of the present disclosure (FIG. 18 to FIG. 20 are top view diagrams, and FIG. 21 is a cross-sectional view diagram), and FIG. 22 is a schematic diagram showing a top view of designs of a transferring substrate according to an embodiment of the present disclosure. Note that the method of manufacturing the electronic device ED of the present disclosure is not limited by the following embodiments and figures. In some embodiments, any other suitable step may be added before or after one of the existing steps of the method, and/or some steps may be performed simultaneously or separately. In some embodiments, the process sequence of the method may be adjusted based on requirement(s). Note that the method of the present disclosure may be able to manufacture a plurality of electronic devices ED.

In the following method of manufacturing the electronic device ED, a forming process of a layer and/or a structure may include an atomic layer deposition (ALD), a chemical vapor deposition (CVD), a physical vapor deposition (PVD), a coating process, any other suitable process or a combination thereof. In the following method of manufacturing the electronic device ED, a patterning process may include a photolithography, an etching process, any other suitable process or a combination thereof, wherein the etching process may be a wet etching process, a dry etching process, any other suitable etching process or a combination thereof.

As shown in FIG. 17 and FIG. 18, in a step ST1 of the method of manufacturing the electronic device ED, a carrier substrate CSB is provided, and the flexible substrate 110 is formed on the carrier substrate CSB (i.e., the flexible substrate 110 is provided), wherein the flexible substrate 110 includes the main portion 112 (the main portion 112 may be referred as the first portion) and the curve portion 114 (the curve portion 114 may be referred as the second portion). In some embodiments, the carrier substrate CSB may be a rigid substrate and include corresponding material. For instance, the carrier substrate CSB may include glass, quartz, ceramic, sapphire, polymer, other suitable materials or a combination thereof. For instance, the flexible substrate 110 may be formed by a coating process, but not limited thereto.

As shown in FIG. 17 and FIG. 18, in a step ST2 of the method of manufacturing the electronic device ED, the circuit layer 130 is formed on the flexible substrate 110, so as to form the electronic components (e.g., the switching components, the pads BD, etc.) in the circuit layer 130. Optionally, the pixel defining layer PDL may be formed on the circuit layer 130. Since the method of the present disclosure may be able to manufacture a plurality of electronic devices ED, the formed circuit layer 130 may be defined to have a plurality of repeating units RU, and the number of the repeating units RU may be the same as the number of the electronic devices ED that need to be manufactured.

As shown in FIG. 17 and FIG. 18, in a step ST3 of the method of manufacturing the electronic device ED, the curve portion 114 of the flexible substrate 110 is patterned by a patterning process, so as to form a plurality of trenches TL. The trench TL may be situated in the repeating unit RU, and the trench TL may pass through the flexible substrate 110 and be corresponding to the aforementioned first substrate opening OPS1 and/or the aforementioned second substrate opening OPS2 of the curve portion 114 of the flexible substrate 110.

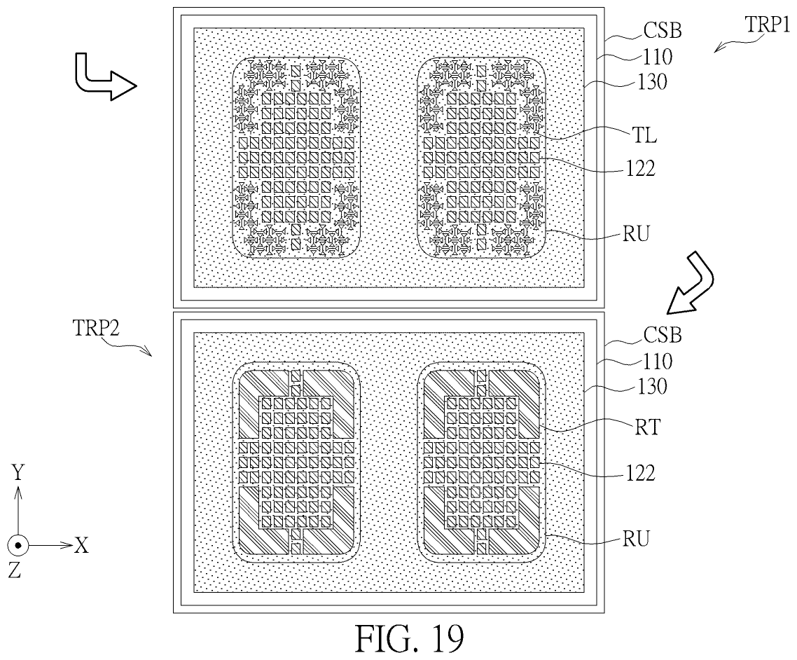

As shown in FIG. 17 and FIG. 19, in a step ST4 of the method of manufacturing the electronic device ED, a plurality of electronic units 120 are transferred to the pads BD of the circuit layer 130 by at least one transfer process, and the electronic units 120 are bonded on the pads BD (i.e., the transfer process includes a bonding process), wherein the number of the electronic unit(s) 120 transferred by the transfer process and the type of the transfer process may be designed based on requirement(s). In some embodiments, one transfer process may transfer a plurality of electronic units 120. For example, in FIG. 17, the step of patterning the curve portion 114 of the flexible substrate 110 may be performed before performing the step of transferring the electronic units 120, but not limited thereto. For example, the transfer process may be a fluid transfer process. For example, the transfer process may be a stamp transfer process, but not limited thereto. For example, the transfer process may be a laser transfer process, such that an energy of the transfer process is provided from a laser beam (e.g., the electronic units 120 to be transferred is transferred to the pads BD of the circuit layer 130 after being irradiated by the laser beam), but not limited thereto.

In some embodiments (as shown in FIG. 19 and FIG. 22), a plurality of main-portion electronic units 122 (or referred as the first electronic units) disposed on a first transferring substrate TSB1 are transferred to the main-portion pads BDm of the circuit layer 130 through at least one first transfer process TRP1, and a plurality of curving-portion electronic units 124 (or referred as the second electronic units) disposed on a second transferring substrate TSB2 are transferred to the curving-portion pads BDb of the circuit layer 130 through at least one second transfer process TRP2 (in FIG. 19, after completing the second transfer process(es) TRP2, the curve portion 114 is shown through four regions RT). Namely, the main-portion electronic unit 122 and the curving-portion electronic unit 124 may be transferred to the pads BD of the circuit layer 130 through different transfer processes. For example (as shown in FIG. 19), the first transfer process TRP1 is performed before performing the second transfer process TRP2 (i.e., the step of transferring the main-portion electronic unit 122 is performed before performing the step of transferring the curving-portion electronic unit 124), but not limited thereto.

In the present disclosure, the number of the main-portion electronic unit(s) 122 transferred by one first transfer process TRP1 and the number of the curving-portion electronic unit(s) 124 transferred by one second transfer process TRP2 may be designed based on requirement(s). In FIG. 22, one first transfer process TRP1 may transfer the main-portion electronic units 122 included in a transferring unit TU1 (i.e., the number of the main-portion electronic units 122 transferred by one first transfer process TRP1 may be the same as the number of the main-portion electronic units 122 included in the transferring unit TU1), and one second transfer process TRP2 may transfer the curving-portion electronic units 124 included in a transferring unit TU2 (i.e., the number of the curving-portion electronic units 124 transferred by one second transfer process TRP2 may be the same as the number of the curving-portion electronic units 124 included in the transferring unit TU2). In some embodiments, the number of the main-portion electronic units 122 transferred by one first transfer process TRP1 may be different from the number of the curving-portion electronic units 124 transferred by one second transfer process TRP2. For instance, (as shown in FIG. 22), the number of the main-portion electronic units 122 transferred by one first transfer process TRP1 (e.g., eighteen main-portion electronic units 122) may be greater than the number of the curving-portion electronic units 124 transferred by one second transfer process TRP2 (e.g., six curving-portion electronic units 124), but not limited thereto. Since the curve portion 114 of the flexible substrate 110 may be bent and/or stretched, a density of the curving-portion electronic units 124 on the curve portion 114 of the flexible substrate 110 may be different from (e.g., less than) a density of the curving-portion electronic units 124 on the second transferring substrate TSB2.

In addition, in a condition that a rotating relation exists between the main-portion pad BDm and the curving-portion pad BDb (the embodiment shown in FIG. 2), a rotating relation should exist between the main-portion electronic unit 122 and the curving-portion electronic unit 124, such that this rotating relation needs to be considered when transferring the curving-portion electronic units 124 in the second transfer process TRP2. For instance, some process devices in the second transfer process TRP2 need to be rotated relative to the first transfer process TRP1, so as to make a required rotating relation exist between the main-portion electronic unit 122 and the curving-portion electronic unit 124.

In FIG. 22, the arrangement of the electronic units 120 on the transferring substrate may be designed based on requirement(s). For instance (e.g., the first transferring substrate TSB1 and a structure TD1 of the second transferring substrate TSB2 shown in FIG. 22), the density of the main-portion electronic units 122 on the first transferring substrate TSB1 may be different from (e.g., greater than) the density of the curving-portion electronic units 124 on the second transferring substrate TSB2. In this case, one first transfer process TRP1 may transfer all main-portion electronic units 122 in a region, and one second transfer process TRP2 may transfer all curving-portion electronic units 124 in a region, but not limited thereto. For instance (e.g., the first transferring substrate TSB1 and a structure TD2 of the second transferring substrate TSB2 shown in FIG. 22), the density of the main-portion electronic units 122 on the first transferring substrate TSB1 may be the same as the density of the curving-portion electronic units 124 on the second transferring substrate TSB2. In this case, one first transfer process TRP1 may transfer all main-portion electronic units 122 in a region, and one second transfer process TRP2 may transfer several non-adjacent curving-portion electronic units 124, but not limited thereto.

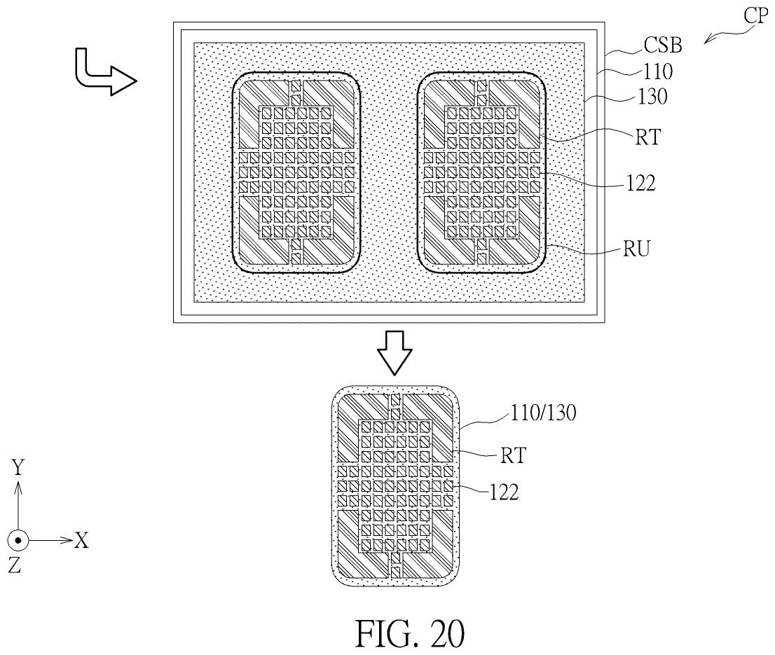

As shown in FIG. 17 and FIG. 20, in a step ST5 of the method of manufacturing the electronic device ED, the flexible substrate 110 is cut by a cutting process CP, wherein the cutting process CP may cut along edges of the repeating units RU (cutting lanes are indicated by a coarse line in FIG. 20), such that the repeating units RU may be separated by a subsequent process. In the present disclosure, the cutting process CP may use any suitable manner to cut the flexible substrate 110.

Optionally, some substrate openings of the flexible substrate 110 may be formed by this cutting process CP. For instance, the first substrate opening OPS1 of the flexible substrate 110 may be formed by this cutting process CP optionally, but not limited thereto.

As shown in FIG. 17, FIG. 20 and FIG. 21, in a step ST6 of the method of manufacturing the electronic device ED, the curve portion 114 of the flexible substrate 110 is bent with respect to the main portion 112 of the flexible substrate 110, so as to make the flexible substrate 110 (i.e., the electronic device ED) achieve the desired shape.

As shown in FIG. 17 and FIG. 20, in a step ST6a included in the step ST6, the carrier substrate CSB is removed. In some embodiments, the flexible substrate 110 is separated (e.g., peeled off) from the carrier substrate CSB through a separating process. Namely, the repeating unit RU is separated from the carrier substrate CSB according to the cutting lanes caused by the cutting process CP. In the present disclosure, the separating process may use any suitable manner to separate the flexible substrate 110 from the carrier substrate CSB. After removing the carrier substrate CSB, since the trench TL of the curve portion 114 passes through the flexible substrate 110, the trench TL may be changed to the first substrate opening OPS1 or the second substrate opening OPS2.

As shown in FIG. 17, FIG. 20 and FIG. 21, in a step ST6b included in the step ST6, a lower substrate BSB is attached to a first side of the flexible substrate 110 away from the circuit layer 130 (i.e., the flexible substrate 110 is between the lower substrate BSB and the circuit layer 130), wherein a rigidity of the lower substrate BSB may be greater than a rigidity of the flexible substrate 110, such that the lower substrate BSB may support the flexible substrate 110 and provide high mechanical strength. In some embodiments, although the rigidity of the lower substrate BSB is greater than the rigidity of the flexible substrate 110, the lower substrate BSB may still have flexibility. For instance, the lower substrate BSB may include any flexible material, such as polymer (e.g., PI, PET, PMMA, etc.), other suitable flexible materials or a combination thereof.

As shown in FIG. 17 and FIG. 21, in a step ST6c included in the step ST6, a second side of the flexible substrate 110 opposite to the first side is attached to a curved cover CV (i.e., the flexible substrate 110 is between the lower substrate BSB and the curved cover CV). In some embodiments, the shape of the curved cover CV may be corresponding to the desired shape of the electronic device ED, and thus, after attaching the flexible substrate 110 to the curved cover CV, the curve portion 114 of the flexible substrate 110 is appropriately bent and/or stretched based on the shape of the curved cover CV, so as to make the flexible substrate 110 (i.e., the electronic device ED) achieve the desired shape, thereby completing the manufacture of the electronic device ED. For example, the curved cover CV may include any suitable rigid material, such that the curve portion 114 of the flexible substrate 110 may be appropriately bent and/or stretched based on the shape of the curved cover CV, and the curved cover CV may protect the flexible substrate 110 and the structures between the curved cover CV and the flexible substrate 110, but not limited thereto.

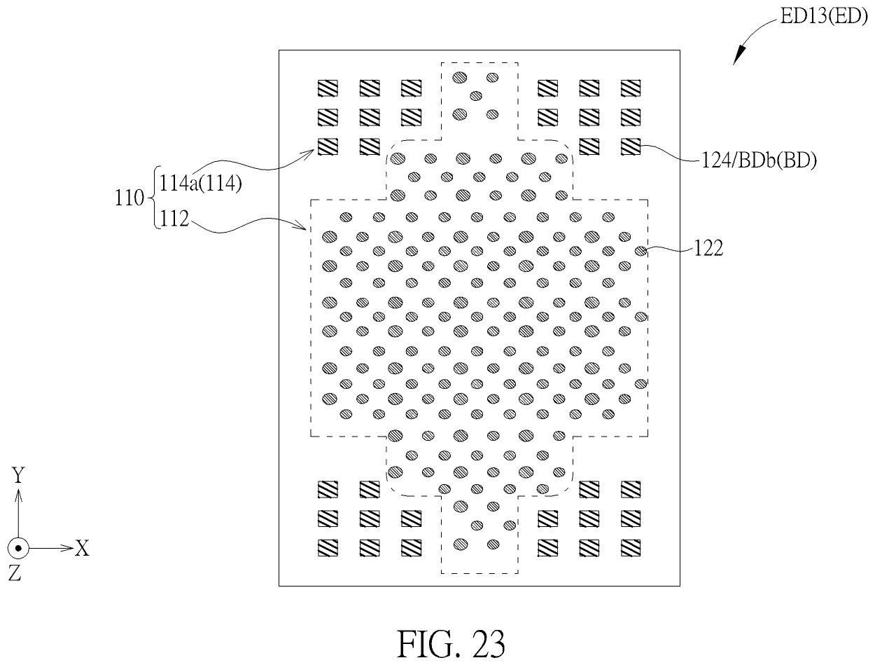

FIG. 23 is a schematic diagram showing a top view of an electronic device according to a thirteenth embodiment of the present disclosure. As shown in FIG. 23, a difference between this embodiment and the first embodiment is the design of the main-portion electronic unit 122 of the electronic device ED13. In FIG. 23, the main-portion electronic unit 122 may be an electronic component disposed on the flexible substrate 110 without going through the transfer process (the bonding process). For instance, the main-portion electronic unit 122 may be an organic light emitting diode (OLED), and the main-portion electronic unit 122 may be formed by a deposition process (e.g., an evaporation process), but not limited thereto. Therefore, the forming method (e.g., the deposition process) of the main-portion electronic unit 122 may be different from the forming method (e.g., the transfer process) of the curving-portion electronic unit 124. In some embodiments, the main-portion electronic unit 122 may be formed in the step of forming the circuit layer 130 (i.e., the step ST2 in FIG. 17), but not limited thereto.

Accordingly, in this embodiment, the pads BD of the circuit layer 130 may include the curving-portion pads BDb and not include the main-portion pad, and the pads BD may optionally include the second redundant pads BDr2.

In summary, in the electronic device of the present disclosure, through the appropriate design of the pads and the curving-portion electronic units on the curve portion of the flexible substrate, the falling possibility and/or the damage of the curving-portion electronic unit is reduced, thereby improving the reliability of the electronic device.

Although the embodiments and their advantages of the present disclosure have been described as above, it should be understood that any person having ordinary skill in the art can make changes, substitutions, and modifications without departing from the spirit and scope of the present disclosure. In addition, the protecting scope of the present disclosure is not limited to the processes, machines, manufactures, material compositions, devices, methods and steps in the specific embodiments described in the description. Any person having ordinary skill in the art can understand the current or future developed processes, machines, manufactures, material compositions, devices, methods and steps from the content of the present disclosure, and then, they can be used according to the present disclosure as long as the same functions can be implemented or the same results can be achieved in the embodiments described herein. Thus, the protecting scope of the present disclosure includes the above processes, machines, manufactures, material compositions, devices, methods and steps. Moreover, each claim constitutes an individual embodiment, and the protecting scope of the present disclosure also includes the combination of each claim and each embodiment. The protecting scope of the present disclosure shall be determined by the appended claims.

Those skilled in the art will readily observe that numerous modifications and alterations of the device and method may be made while retaining the teachings of the disclosure. Accordingly, the above disclosure should be construed as limited only by the metes and bounds of the appended claims.

What is claimed is:

1. An electronic device, comprising:
a flexible substrate comprising a main portion and a curve portion connected to the main portion;
a circuit layer disposed on the flexible substrate, comprising a first pad disposed on the main portion and a second pad disposed on the curve portion;
a first electronic unit bonded on the first pad; and
a second electronic unit bonded on the second pad;
wherein an area of the second pad is different from an area of the first pad.

2. The electronic device according to claim 1, wherein a ratio of the area of the first pad to the area of the second pad is not equal to 1.

3. The electronic device according to claim 1, wherein the circuit layer further comprises a first circuit electrically connected to the first pad and a second circuit electrically connected to the second pad.

4. The electronic device according to claim 3, further comprising a first redundant pad disposed on the main portion and electrically connected to the first circuit and a second redundant pad disposed on the curve portion and electrically connected to the second circuit, wherein an area of the second redundant pad is different from an area of the first redundant pad.

5. The electronic device according to claim 3, further comprising at least one first redundant pad disposed on the main portion and electrically connected to the first circuit and at least two second redundant pads disposed on the curve portion and electrically connected to the second circuit, wherein a number of the at least two second redundant pads is greater than a number of the at least one first redundant pad.

6. The electronic device according to claim 1, wherein the curve portion comprises a corner region, and the second pad is disposed on the corner region.

7. The electronic device according to claim 1, wherein the second pad comprises a plurality of openings.

8. The electronic device according to claim 1, wherein an area of the second electronic unit is different from an area of the first electronic unit.

9. An electronic device, comprising:
a flexible substrate comprising a main portion and a curve portion connected to the main portion;
a circuit layer disposed on the flexible substrate, comprising a first pad, a second pad, a third pad, a fourth pad, a fifth pad, a sixth pad, a seventh pad and an eighth pad, wherein the first pad, the second pad, the third pad and the fourth pad are disposed on the main portion, and the fifth pad, the sixth pad, the seventh pad and the eighth pad are disposed on the curve portion;
a first electronic unit bonded on the first pad and the second pad;
a second electronic unit bonded on the third pad and the fourth pad;
a third electronic unit bonded on the fifth pad and the sixth pad; and
a fourth electronic unit bonded on the seventh pad and the eighth pad;
wherein a first axis crossing a first center of the first pad and the second pad and a second center of the third pad and the fourth pad is not parallel to a second axis crossing a third center of the fifth pad and the sixth pad and a fourth center of the seventh pad and the eighth pad.

10. The electronic device according to claim 9, wherein an angle between the first axis and the second axis is greater than or equal to 5 degrees and less than or equal to 90 degrees.

11. The electronic device according to claim 9, wherein an area of the third electronic unit is different from an area of the first electronic unit.

12. The electronic device according to claim 9, wherein each of the fifth pad, the sixth pad, the seventh pad and the eighth pad comprises a plurality of openings.

13. The electronic device according to claim 9, wherein a third axis crossing a center of the first pad and a center of the second pad is parallel to a fourth axis crossing a center of the fifth pad and a center of the sixth pad.

14. The electronic device according to claim 9, wherein a distance between the first pad and the second pad is different from a distance between the fifth pad and the sixth pad.

15. The electronic device according to claim 9, wherein a distance between the fifth pad and the sixth pad is different from a distance between the seventh pad and the eighth pad.

16. A method of manufacturing an electronic device, comprising following steps:
providing a flexible substrate, wherein the flexible substrate comprises a first portion and a second portion;
forming a circuit layer on the flexible substrate, wherein the circuit layer comprises a plurality of first pads disposed on the first portion and a plurality of second pads disposed on the second portion;
patterning the second portion to form a plurality of trenches;
transferring a plurality of first electronic units to the plurality of first pads by at least one first transfer process;
transferring a plurality of second electronic units to the plurality of second pads by at least one second transfer process; and
bending the second portion with respect to the first portion;
wherein a number of the first electronic units transferred by one of the at least one first transfer process is different from a number of the second electronic units transferred by one of the at least one second transfer process.

17. The method according to claim 16, wherein the step of transferring the plurality of first electronic units is performed before performing the step of transferring the plurality of second electronic units.

18. The method according to claim 16, wherein the step of patterning the second portion is performed before performing the step of transferring the plurality of first electronic units.

19. The method according to claim 16, wherein the step of providing the flexible substrate comprises:
providing a carrier substrate; and
forming the flexible substrate on the carrier substrate.

20. The method according to claim 19, wherein the step of bending the second portion comprises:
removing the carrier substrate;
attaching a lower substrate to a first side of the flexible substrate away from the circuit layer; and
attaching a second side of the flexible substrate to a curved cover, wherein the second side is opposite to the first side.
